(19) United States
(12) Patent Application Publication
(10) Pub. No.: US 2024/0047506 A1
(43) Pub. Date: Feb. 8, 2024

(54) LIGHT-EMITTING ELEMENT AND DISPLAY DEVICE

(71) Applicant: LG ELECTRONICS INC., Seoul (KR)

(72) Inventor: Bongchu SHIM, Seoul (KR)

(73) Assignee: LG ELECTRONICS INC., Seoul (KR)

(21) Appl. No.: 18/269,504

(22) PCT Filed: Jan. 6, 2021
(86) PCT No.: PCT/KR2021/000115

§ 371 Date: Jun. 23, 2023

(51) Int. Cl. H01L 27/15; H01L 33/24; H01L 33/40

(52) U.S. Cl. CPC H01L 27/156; H01L 33/24; H01L 33/40

(57) ABSTRACT

The light emitting device can include a first conductivity type semiconductor layer, an active layer on the first conductivity type semiconductor layer, a second conductivity type semiconductor layer on the active layer, at least one or more electrode layers on the second conductivity type semiconductor layer, and an insulating layer on the electrode layer. At least one of the second conductivity type semiconductor layer and the electrode layer can be positioned in the central region of the light emitting device.

Therefore, even if a plurality of light emitting devices are disposed on a substrate of a display device having different assembly directions, all light emitting devices assembled on the substrate can emit light without defects.

### TECHNICAL FIELD

The embodiment relates to a light emitting device and a display device.

### BACKGROUND ART

A display device displays a high-quality image by using a self-light emitting device such as a light emitting diode as a light source of a pixel. The light emitting diode has excellent durability, long lifespan, and high luminance even under harsh environmental conditions, and are in the limelight as a light source for next-generation display devices.

Recently, a super small-sized light emitting diode is manufactured using a material having a highly reliable inorganic crystal structure, and the super small-sized light emitting diode is disposed on a panel of a display device (hereinafter referred to as a “display panel”) such that a light source is manufactured and research is being conducted to use it as a next-generation light source for pixel.

In order to implement high resolution, a size of pixel is gradually getting smaller, and a number of the light emitting devices are arranged in the pixel of such a reduced size. Accordingly, research on the manufacture of super small-sized light emitting diode as small as micro or nano scale is being actively conducted.

Generally, a display panel includes millions of pixels. It is very difficult to align light emitting devices to each of millions of small-sized pixels. Accordingly, various studies on a method of aligning light emitting devices on a display panel have recently been actively conducted.

As the size of light emitting devices decreases, transferring these light emitting devices onto a substrate has become a very important problem. Transfer technologies that have recently been developed include a pick and place process, a laser lift-off method, or a self-assembly method. In particular, a self-assembly method in which a light emitting device is transferred onto a substrate using a magnetic material (or magnet) has recently been in the spotlight.

In the self-assembly method, a light emitting device is disposed in each sub-pixel by using an inkjet head device to drop a liquid droplet comprising a light emitting device onto a substrate. Since the light emitting devices are randomly dropped on the substrate, some light emitting devices can be correctly assembled between the electrodes while others may not be correctly assembled between the electrodes.

As shown in FIG. 1, the light emitting devices 2 and 3 dropped from the inkjet head device by the dielectrophoretic force formed between the first electrode 1a and the second electrode 1b are assembled between the first electrode 1a and the second electrode 1b. At this time, the light emitting devices 2 and 3 are not assembled with a certain assembly direction.

That is, in some light emitting devices 3, the N electrode is positioned on the first electrode 1a and the P electrode is positioned on the second electrode 1b, but in other light emitting devices 2, the N electrode is positioned on the second electrode 1b and the P electrode is positioned on the first electrode 1a. When a positive (+) voltage is applied to the first electrode (1a) and a negative (−) voltage is applied to the second electrode (1b), the light emitting devices 2 in which the P electrode is positioned on the first electrode 1a and the N electrode is positioned on the second electrode 1b emit light, contributing to an increase in luminance of each pixel. However, the light emitting devices 3 in which the N electrode is positioned on the first electrode 1a and the P electrode is positioned on the second electrode 1b do not emit light and do not contribute to increasing the luminance of each pixel.

Since the light emitting devices 2 and 3 are randomly assembled between the first electrode 1a and the second electrode 1b, typically, about 50% of the number of the light emitting devices 2 and 3 assembled between the first electrode 1a and the second electrode 1b can be defective light emitting devices that do not emit light.

Therefore, in the related art, there has been a problem in that cost is increased due to defective light emitting devices that do not contribute to an increase in luminance of each pixel.

In addition, in the related art, there was a problem in that it was impossible to implement a high-brightness display due to low luminance due to a considerable amount of defective light emitting devices.

### DISCLOSURE

### Technical Problem

An object of the embodiment is to solve the foregoing and other problems.

Another object of the embodiment is to provide a light emitting device and a display device capable of emitting light regardless of assembly direction.

Another object of the embodiments is to provide a light emitting device and a display device capable of significantly reducing costs.

Another object of the embodiments is to provide a light emitting device and a display device capable of remarkably improving luminance.

Another object of the embodiment is to provide a light emitting device and a display device capable of securing uniformity of luminance of each pixel.

### Technical Solution

According to one aspect of the embodiment to achieve the above or other object, a light emitting device, comprising: a first conductivity type semiconductor layer; an active layer on the first conductivity type semiconductor layer; a second conductivity type semiconductor layer on the active layer; at least one or more electrode layers on the second conductivity type semiconductor layer; and an insulating layer on the at least one or more electrode layers, wherein at least one of the second conductivity type semiconductor layer and the electrode layer is configured to be positioned in the central region of the light emitting device.

According to another aspect of the embodiment, a display device, comprising: a substrate; a first wiring line on the substrate; a second wiring line on the substrate; an insulating member comprising a plurality of assembly holes on the first wiring line and the second wiring line; a plurality of light emitting devices in each of the plurality of assembly holes; a first electrode line configured to cross the central region of each of the plurality of light emitting devices; and a second electrode line configured to cross both side regions of each of the plurality of light emitting devices, wherein the light emitting device comprises: a first conductivity type semiconductor layer; an active layer on the first conductivity type semiconductor layer, a second conductivity type semiconductor layer on the active layer; at least one or more electrode layers on the second conductivity type semiconductor layer; and an insulating layer on the at least one or more electrode layers, wherein at least one of the second conductivity type semiconductor layer and the electrode layer is configured to be positioned in the central region of the light emitting device.

According to another aspect of the embodiment, a display device, comprising: a substrate; a first wiring line on the substrate; a second wiring line on the substrate; an insulating member comprising a plurality of assembly holes on the first wiring line and the second wiring line; a plurality of light emitting devices in each of the plurality of assembly holes; an electrode line configured to cross the central region of each of the plurality of light emitting devices; and contact electrodes disposed on the insulating member and configured to connect both side regions of each of the plurality of light emitting devices to the first wiring line and the second wiring line, wherein the light emitting device comprises: a first conductivity type semiconductor layer; an active layer on the first conductivity type semiconductor layer; a second conductivity type semiconductor layer on the active layer; at least one or more electrode layers on the second conductivity type semiconductor layer; and an insulating layer on the at least one or more electrode layers, wherein at least one of the second conductivity type semiconductor layer and the electrode layer is configured to be positioned in the central region of the light emitting device.

According to another aspect of the embodiment, a light emitting device, comprising: a first conductivity type semiconductor layer; a first active layer on the first conductivity type semiconductor layer; a second conductivity type semiconductor layer on the first active layer; at least one or more electrode layers on the second conductivity type semiconductor layer; a third conductivity type semiconductor layer on the at least one or more electrode layers; a second active layer on the third conductivity type semiconductor layer; and a fourth conductivity type semiconductor layer on the second active layer, wherein the first conductivity type semiconductor layer and the fourth conductivity type semiconductor layer comprise the same dopant, wherein the second conductivity type semiconductor layer and the third conductivity type semiconductor layer comprise the same dopant, and wherein the at least one or more electrode layers are configured to be positioned in the central region of the light emitting device.

According to another aspect of the embodiment, a display device, comprising: a substrate; a first wiring line on the substrate; a second wiring line on the substrate; an insulating member comprising a plurality of assembly holes on the first wiring line and the second wiring line; a plurality of light emitting devices in each of the plurality of assembly holes; a first electrode line configured to cross the central region of each of the plurality of light emitting devices; and a second electrode line configured to cross both side regions of each of the plurality of light emitting devices, wherein the light emitting device comprises: a first conductivity type semiconductor layer; a first active layer on the first conductivity type semiconductor layer; a second conductivity type semiconductor layer on the first active layer; at least one or more electrode layers on the second conductivity type semiconductor layer; a third conductivity type semiconductor layer on the at least one or more electrode layers; a second active layer on the third conductivity type semiconductor layer; and a fourth conductivity type semiconductor layer on the second active layer, wherein the first conductivity type semiconductor layer and the fourth conductivity type semiconductor layer comprise the same dopant, wherein the second conductivity type semiconductor layer and the third conductivity type semiconductor layer comprise the same dopant, and wherein the at least one or more electrode layers are configured to be positioned in the central region of the light emitting device.

According to another aspect of the embodiment, a display device, comprising: a substrate; a first wiring line on the substrate; a second wiring line on the substrate; an insulating member comprising a plurality of assembly holes on the first wiring line and the second wiring line; a plurality of light emitting devices in each of the plurality of assembly holes; and an electrode line configured to cross the central region of each of the plurality of light emitting devices; and contact electrodes disposed on the insulating member and configured to connect both side regions of each of the plurality of light emitting devices to the first wiring line and the second wiring line, wherein the light emitting device comprises: a first conductivity type semiconductor layer; a first active layer on the first conductivity type semiconductor layer; a second conductivity type semiconductor layer on the first active layer; at least one or more electrode layers on the second conductivity type semiconductor layer; a third conductivity type semiconductor layer on the at least one or more electrode layers; a second active layer on the third conductivity type semiconductor layer; and a fourth conductivity type semiconductor layer on the second active layer, wherein the first conductivity type semiconductor layer and the fourth conductivity type semiconductor layer comprise the same dopant, wherein the second conductivity type semiconductor layer and the third conductivity type semiconductor layer comprise the same dopant, and wherein the at least one or more electrode layers are configured to be positioned in the central region of the light emitting device.

### Advantageous Effects

Effects of the light emitting device and the display device according to the embodiment are described as follows.

According to at least one of the embodiments, as shown in FIG. 10, in a light emitting device composed of a first conductivity type semiconductor layer, an active layer, a second conductivity type semiconductor layer, at least one or more electrode layers and an insulating layer, the second conductivity type semiconductor layer and/or the electrode can be positioned in the central region of the light emitting device.

When the light emitting device configured as described above is assembled into a display device, as shown in FIGS. 11 and 12, the first electrode line can be disposed to cross the second conductivity type semiconductor layer and/or the electrode positioned in the central region of each of the plurality of light emitting devices, and the second electrode line can be disposed to cross the first conductivity type semiconductor layer or the insulating layer positioned on both side regions of each of the plurality of light emitting devices.

Also, as shown in FIGS. 14 and 15, the electrode line can be disposed to cross the second conductivity type semiconductor layer and/or the electrode positioned in the central region of each of the plurality of light emitting devices, and an connection electrodes can be disposed to cross the first conductivity type semiconductor layer or the insulating layer positioned on both side regions of each of the plurality of light emitting devices, and can be electrically connected to the first wiring line and the second wiring line. Accordingly, even when a plurality of light emitting devices are disposed in different assembly directions in a display device, all light emitting devices assembled on the substrate can emit light without defects.

Therefore, in the embodiment, since no defective light emitting device exists for each pixel, it is possible to significantly reduce costs by preventing waste of defective light emitting devices. In addition, since about 50% of the light emitting devices for each pixel can emit more light than in the related art, the luminance can be remarkably improved, enabling a high luminance display. In addition, since defective light emitting devices do not occur for each pixel, when a uniform number of the light emitting devices is assembled in each pixel, a uniform luminance can be secured and more precise luminance control is possible.

According to at least one of the embodiments, as shown in FIG. 16, the light emitting device comprises a first light emitting device and a second light emitting device having a structure symmetrical to each other on both sides with respect to at least one or more electrode layers positioned in the central region of the light emitting device. The first light emitting device can be formed below the electrode layer in the order of the second conductivity type semiconductor layer, the first active layer and the first conductivity type semiconductor layer, and the second light emitting device can be formed on the electrode layer in the order of the third conductivity type semiconductor layer, the second active layer and the fourth conductivity type semiconductor layer. In this case, the first conductivity type semiconductor layer and the fourth conductivity type semiconductor layer can comprise the same dopant, and the second conductivity type semiconductor layer and the third conductivity type semiconductor layer can comprise the same dopant.

By adopting the light emitting device configured as described above in a display device (FIGS. 17 to 20), it is possible to emit light in two different light emitting areas in one light emitting device so that the amount of light can be further increased and the luminance can be improved. In addition, since the number of the light emitting devices assembled in each pixel is reduced to obtain the same luminance in each pixel, assembly defects can be further reduced as the number of the light emitting devices is reduced.

A further scope of applicability of the embodiment will become apparent from the detailed description that follows. However, since various changes and modifications within the spirit and scope of the embodiment can be clearly understood by those skilled in the art, it should be understood that the detailed description and specific embodiment, such as preferred embodiment, are given by way of example only.

### DESCRIPTION OF DRAWINGS

FIG. 1 shows a view in which a light emitting device is assembled.

FIG. 2 illustrates a living room of a house in which a display device according to an embodiment is disposed.

FIG. 3 is a schematic block diagram of a display device according to an embodiment.

FIG. 4 is a circuit diagram showing an example of a pixel of FIG. 3.

FIG. 5 is a plan view showing the display panel of FIG. 3 in detail.

FIG. 6 is a plan view showing pixels of the display area of FIG. 5 in detail.

FIG. 7 is an enlarged view of a first panel area in the display device of FIG. 2.

FIG. 8 is an enlarged view of the area A2 of FIG. 7.

FIG. 9 is a view showing an example in which a light emitting device according to an embodiment is assembled to a substrate by a self-assembly method.

FIG. 10 is a cross-sectional view illustrating a light emitting device according to a first embodiment.

FIG. 11 is a plan view illustrating a first example of a display device having a light emitting device according to the first embodiment.

FIG. 12 is a cross-sectional view taken along line A-B of FIG. 11.

FIG. 13 is a plan view illustrating a second example of a display device having a light emitting device according to the first embodiment.

FIG. 14 is a plan view illustrating a third example of a display device having a light emitting device according to the first embodiment.

FIG. 15 is a cross-sectional view taken along line C-D of FIG. 14.

FIG. 16 is a cross-sectional view illustrating a light emitting device according to a second embodiment.

FIG. 17 is a plan view illustrating a first example of a display device having a light emitting device according to a second embodiment.

FIG. 18 is a cross-sectional view taken along line E-F of FIG. 17.

FIG. 19 is a plan view illustrating a second example of a display device having a light emitting device according to the second embodiment.

FIG. 20 is a cross-sectional view taken along line G-H of FIG. 19.

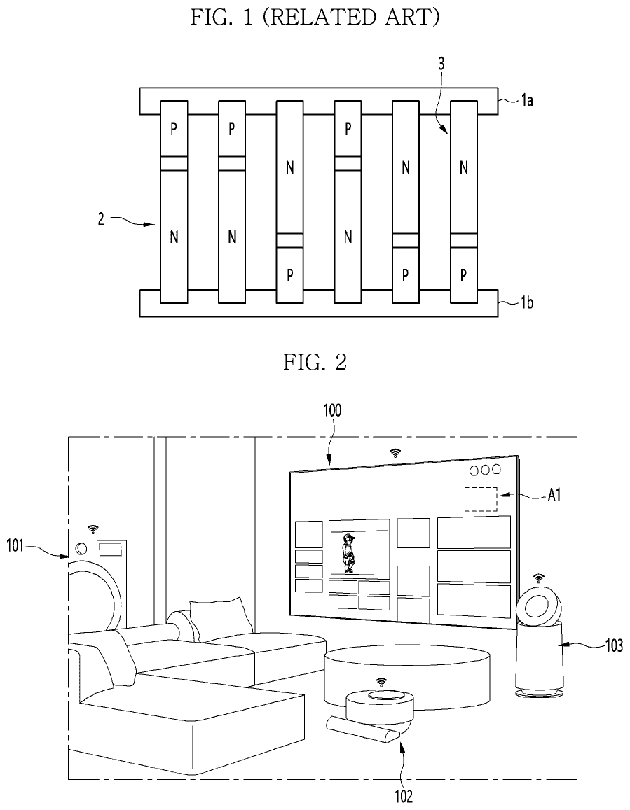

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there can be directly on the other element or be other intermediate elements therebetween.

The display device described in this specification can comprise TV, the signage, a mobile phone, a smart phone, a head-up display (HUD) for a vehicle, a backlight unit for a laptop computer, a display for VR, AR, MR, XR or the like. However, the configuration according to the embodiment described in this specification can be applied to a display-capable device even if it is a new product type to be developed in the future.

Hereinafter, a light emitting device according to an embodiment and a display device comprising the light emitting device ill be described.

FIG. 2 illustrates a living room of a house in which a display device according to an embodiment is disposed.

Referring to FIG. 2, the display device 100 of the embodiment can display the status of various electronic products such as a washing machine 101, a robot cleaner 102, and an air purifier 103, communicate with each electronic product based on IOT and control each electronic product based on user's setting data.

The display device 100 according to the embodiment can include a flexible display manufactured on a thin and flexible substrate. The flexible display can be bent or rolled like paper while maintaining the characteristics of an existing flat panel display.

In the flexible display, visual information can be implemented by independently controlling light emission of a unit pixel arranged in a matrix form. The unit pixel means a minimum unit for implementing one color. The unit pixel of the flexible display can be implemented by a light emitting device. In the embodiment, the light emitting device can be Micro-LED or Nano-LED, but is not limited thereto.

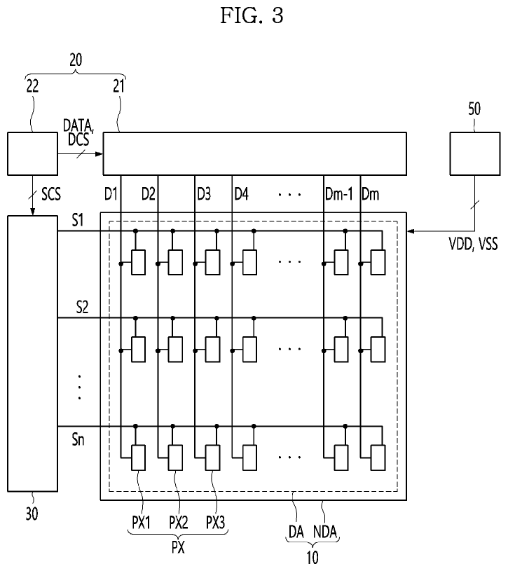

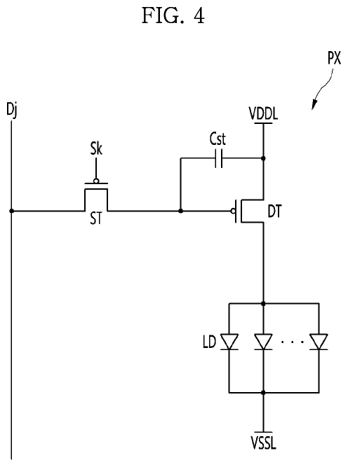

FIG. 3 is a schematic block diagram of a display device according to an embodiment, and FIG. 4 is a circuit diagram showing an example of a pixel of FIG. 3.

Referring to FIG. 3 and FIG. 4, a display device according to an embodiment can comprise a display panel 10, a driving circuit 20, a scan driving circuit 30 and a power supply circuit 50.

The display device 100 of the embodiment can drive a light emitting device in an active matrix (AM) scheme or a passive matrix (PM) scheme.

The driving circuit 20 can comprise a data driving circuit 21 and a timing controller 22.

The display panel 10 can have a rectangular shape, but is not limited thereto. That is, the display panel 10 can be formed in a circular or elliptical shape. At least one side of the display panel 10 can be formed to be bent with a predetermined curvature.

The display panel 10 can be divided into a display area DA and a non-display area NDA disposed around the display area DA. The display area DA is an area where the pixels PX are formed to display an image. The display panel 10 can comprise data lines (D1 to Dm, where in is an integer greater than or equal to 2), scan lines (S1 to Sn, where n is an integer greater than or equal to 2) crossing the data lines (D1 to Dm), a high potential voltage line VDDL supplied with a high potential voltage, a low potential voltage line VSSL supplied with a low potential voltage, and pixels PX connected to the data lines D1 to Dm and the scan lines S1 to Sn.

Each of the pixels PX can comprise a first sub-pixel PX1, a second sub-pixel PX2, and a third sub-pixel PX3. The first sub-pixel PX1 can emit a first color light with a first main wavelength, the second sub-pixel PX2 can emit of a second color light with a second main wavelength, and the third sub-pixel PX3 can emit a third color light with a third main wavelength. The first color light can be red light, the second color light can be green light, and the third color light can be blue light, but are not limited thereto. In addition, in FIG. 3, it is illustrated that each of the pixels PX comprise three sub-pixels, but are not limited thereto. That is, each of the pixels PX can comprise four or more sub-pixels.

Each of the first sub-pixel PX1, the second sub-pixel PX2, and the third sub-pixel PX3 can be connected to at least one of the data lines D1 to Dm, at least one of the scan lines S1 to Sn, and a high potential voltage line VDDL. As shown in FIG. 4, the first sub-pixel PX1 can include light emitting devices LDs, a plurality of transistors for supplying current to the light emitting devices LDs, and at least one capacitor Cst.

Each of the light emitting devices LD can be a semiconductor light emitting diode comprising a first electrode, a plurality of conductive semiconductor layers, and a second electrode. Here, the first electrode can be an anode electrode, and the second electrode can be a cathode electrode, but is not limited thereto.

The plurality of transistors can include a driving transistor DT supplying current to the light emitting devices LD and a scan transistor ST supplying a data voltage to a gate electrode of the driving transistor DT, as shown in FIG. 4. The driving transistor DT has a gate electrode connected to the source electrode of the scan transistor ST, a source electrode connected to the high potential voltage line VDDL to which a high potential voltage is applied, and a drain electrode connected to the first electrodes of the light emitting devices LD. The scan transistor ST has a gate electrode connected to the scan line (Sk, k is an integer that satisfies 1≤k≤n), a source electrode connected to the gate electrode of the driving transistor DT, and a drain electrode connected to the data lines (Dj, j an integer that satisfies 1≤j≤m).

The capacitor Cst is formed between the gate electrode and the source electrode of the driving transistor DT. The storage capacitor Cst stores a difference voltage between a gate voltage and a source voltage of the driving transistor DT.

The driving transistor DT and the scan transistor ST can be formed of a thin film transistor. In addition, in FIG. 4, the driving transistor DT and the scan transistor ST have been mainly described as being formed of P-type MOSFETs (Metal Oxide Semiconductor Field Effect Transistors), but are not limited thereto. The driving transistor DT and the scan transistor ST can be formed of N-type MOSFETs. In this case, positions of the source electrode and the drain electrode of each of the driving transistor DT and the scan transistor ST can be changed.

In addition, in FIG. 4, it is illustrated that each of the first sub-pixel PX1, the second sub-pixel PX2, and the third sub-pixel PX3 includes 2TIC (2 Transistor-1 capacitor) having one driving transistor DT, one scan transistor ST, and one capacitor Cst, but is not limited thereto. Each of the first sub-pixel PX1, the second sub-pixel PX2, and the third sub-pixel PX3 can include a plurality of scan transistors ST and a plurality of capacitors Cst.

Since the second sub-pixel PX2 and the third sub-pixel PX3 can be expressed with substantially the same circuit diagram as the first sub-pixel PX1, detailed descriptions will be omitted.

The driving circuit 20 outputs signals and voltages for driving the display panel 10. To this end, the driving circuit 20 can include a data driving circuit 21 and a timing controller 22.

The data driving circuit 21 receives digital video data DATA and a source control signal DCS from the timing controller 22. The data driving circuit 21 converts the digital video data DATA into analog data voltages according to the source control signal DCS and supplies them to the data lines D1 to Dm of the display panel 10.

The timing controller 22 receives digital video data DATA and timing signals from a host system. The timing signals can include a vertical synchronization signal, a horizontal synchronization signal, a datan enable signal, and a dot clock. The host system can be an application processor of a smart phone or tablet PC, a system on chip of a monitor or TV, or the like.

The timing controller 22 generates control signals for controlling operation timings of the data driving circuit 21 and the scan driving circuit 30. The control signals can include a source control signal DCS for controlling the operation timing of the data driving circuit 21 and a scan control signal SCS for controlling the operation timing of the scan driving circuit 30.

The driving circuit 20 can be disposed in the non-display area NDA provided on one side of the display panel 10. The driving circuit 20 can be formed of an integrated circuit (IC) and mounted on the display panel 10 using a chip on glass (COG) scheme, a chip on plastic (COP) scheme, or an ultrasonic bonding scheme, but is not limited thereto. For example, the driving circuit 20 can be mounted on a circuit board (not shown) instead of the display panel 10.

The data driving circuit 21 can be mounted on the display panel 10 using a chip on glass (COG) scheme, a chip on plastic (COP) scheme, or an ultrasonic bonding scheme, and the timing controller 22 can be mounted on a circuit board.

The scan driving circuit 30 receives the scan control signal SCS from the timing controller 22. The scan driving circuit 30 generates scan signals according to the scan control signal SCS and supplies them to the scan lines S1 to Sn of the display panel 10. The scan driving circuit 30 can include a plurality of transistors and be formed in the non-display area NDA of the display panel 10. Alternatively, the scan driving circuit 30 can be formed as an integrated circuit, and in this case, it can be mounted on a gate flexible film attached to the other side of the display panel 10.

The circuit board can be attached to pads provided on one edge of the display panel 10 using an anisotropic conductive film. For this reason, the lead lines of the circuit board can be electrically connected to the pads. The circuit board can be a flexible printed circuit board, a printed circuit board, or a flexible film such as a chip on film. The circuit board can be bent to a lower side of the display panel 10. Accordingly, one side of the circuit board can be attached to one edge of the display panel 10 and the other side can be disposed below the display panel 10 and can be connected to a system board on which a host system is mounted.

The power supply circuit 50 can generate voltages necessary for driving the display panel 10 from the main power supplied from the system board and supply the voltages to the display panel 10. For example, the power supply circuit 50 generates a high potential voltage VDD and a low potential voltage VSS for driving the light emitting devices LD of the display panel 10 from the main power supply to supply them to the high potential voltage line VDDL and the low potential voltage line VSSL. Also, the power supply circuit 50 can generate and supply driving voltages for driving the driving circuit 20 and the scan driving circuit 30 from the main power.

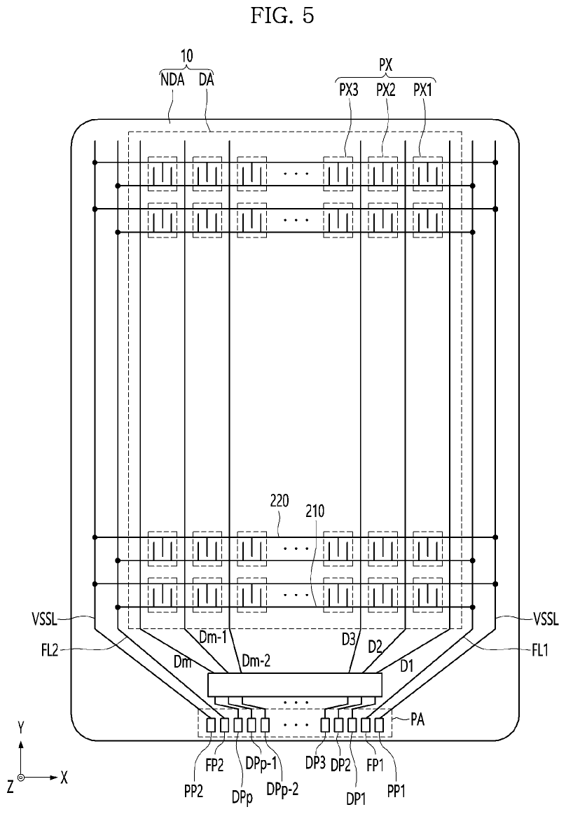

FIG. 5 is a plan view showing the display panel of FIG. 3 in detail. In FIG. 5, for convenience of description, data pads (DP1 to DPₚ, where p is an integer greater than or equal to 2), floating pads FD1 and FD2, power pads PP1 and PP2, floating lines FL1 and FL2, low potential voltage line VSSL, data lines D1 to DM, first electrodes 260 and second electrodes 220 are shown.

Referring to FIG. 5, the data lines D1 to Dm, the first electrodes 210, the second electrodes 220, and the pixels PX can be disposed in the display area DA of the display panel 10.

The data lines D1 to Dm can extend long in the second direction (Y-axis direction). One sides of the data lines D1 to Dm can be connected to the driving circuit 20. For this reason, the data voltages of the driving circuit 20 can be applied to the data lines D1 to Dm.

The first electrodes 210 can be spaced apart from each other at predetermined intervals in the first direction (X-axis direction). For this reason, the first electrodes 210 may not overlap the data lines D1 to Dm. Among the first electrodes 210, the first electrodes 210 disposed on the right edge of the display area DA can be connected to the first floating line FL1 in the non-display area NDA. Among the first electrodes 210, the first electrodes 210 disposed at the left edge of the display area DA can be connected to the second floating line FL2 in the non-display area NDA.

Each of the second electrodes 220 can extend long in the first direction (X-axis direction). For this reason, the second electrodes 220 can overlap the data lines D1 to Dm. Also, the second electrodes 220 can be connected to the low potential voltage line VSSL in the non-display area NDA. For this reason, the low potential voltage of the low potential voltage line VSSL can be applied to the second electrodes 220.

Each of the pixels PX can comprise a first sub-pixel PX1, a second sub-pixel PX2, and a third sub-pixel PX3. The first sub-pixel PX1, the second sub-pixel PX2, and the third sub-pixel PX3 of each of the pixels PX can be arranged in regions defined in a matrix form by the first electrodes 210, the second electrodes 220, and data lines D1 to Dm. Although FIG. 5 illustrates that the pixel PX comprises three sub-pixels, it is not limited thereto, and each of the pixels PX can comprise four or more sub-pixels.

The first sub-pixel PX1, the second sub-pixel PX2, and the third sub-pixel PX3 of each of the pixels PX can be disposed in the first direction (X-axis direction), but are not limited thereto. That is, the first sub-pixel PX1, the second sub-pixel PX2, and the third sub-pixel PX3 of each of the pixels PX are disposed in the second direction (Y-axis direction) or in a zigzag shape and can be arranged in a variety of other forms.

The first sub-pixel PX1 can emit a first color light, the second sub-pixel PX2 can emit a second color light, and the third sub-pixel PX3 can emit a third color light. The first color light can be red light, the second color light can be green light, and the third color light can be blue light, but are not limited thereto.

In the non-display area NDA of the display panel 10, a pad part PA comprising data pads DP1 to DPₚ, floating pads FD1 and FD2, and power pads PP1 and PP2, and a driving circuit 20, a first floating line FL1, a second floating line FL2, and a low potential voltage line VSSL can be disposed.

The pad part PA comprising the data pads DP1 to DPₚ, the floating pads FD1 and FD2, and the power pads PP1 and PP2 can be disposed in one edge of the display panel 10, for example, an edge of the lower side. The data pads DP1 to DPₚ, the floating pads FD1 and FD2, and the power pads PP1 and PP2 can be disposed side by side in the first direction (X-axis direction) of the pad part PA.

A circuit board can be attached using an anisotropic conductive film on the data pads DP1 to DPₚ, the floating pads FD1 and FD2, and the power pads PP1 and PP2. Accordingly, the circuit board, the data pads DP1 to DPₚ, the floating pads FD1 and FD2, and the power pads PP1 and PP2 can be electrically connected.

The driving circuit 20 can be connected to the data pads DP1 to DPₚ through the link lines LL. The driving circuit 20 can receive digital video data DATA and timing signals through the data pads DP1 to DPₚ. The driving circuit 20 can convert the digital video data DATA into analog data voltages and supply them to the data lines D1 to Dm of the display panel 10.

The low potential voltage line VSSL can be connected to the first power pad PP1 and the second power pad PP2 of the pad part PA. The low potential voltage line VSSL can extend long in the second direction (Y-axis direction) in the non-display area NDA located in the left outside and the right outside of the display area DA. The low potential voltage line VSSL can be connected to the second electrode 220. For this reason, the low potential voltage of the power supply circuit 50 is applied to the second electrode 220 through the circuit board, the first power pad PP1, the second power pad PP2 and the low potential voltage line VSSL.

The first floating line FL1 can be connected to the first floating pad FD1 of the pad part PA. The first floating line FL1 can extend long in the second direction (Y-axis direction) in the non-display area NDA located in the left outside and the right outside of the display area DA.

The first floating pad FD1 and the first floating line FL1 can be dummy pads or dummy lines to which no voltage is applied.

The second floating line FL2 can be connected to the second floating pad FD2 of the pad part PA. The first floating line FL1 can extend long in the second direction (Y-axis direction) in the non-display area NDA located in the left outside and the right outside of the display area DA.

The second floating pad FD2 and the second floating line FL2 can be dummy pads or dummy lines to which no voltage is applied.

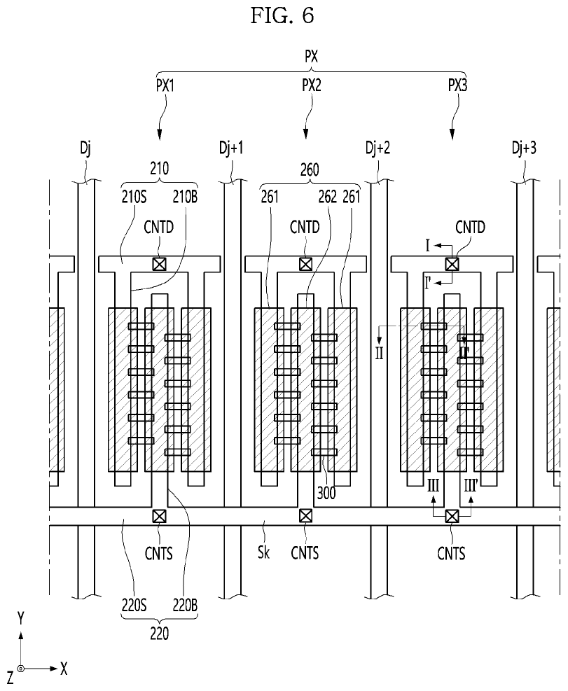

Meanwhile, since the light emitting devices (300 in FIG. 6) have a very small size, it is difficult that they are mounted on the first sub-pixel PX1, the second sub-pixel PX2, and the third sub-pixel PX3 of each of the pixels PX.

In order to solve this problem, an alignment method using a dielectrophoresis scheme has been proposed.

That is, an electric field can be formed in each of the first sub-pixel PX1, the second sub-pixel PX2, and the third sub-pixel PX3 of the pixels PX to align the light emitting devices 300 during the manufacturing process. Specifically, the light emitting devices 300 can be aligned by applying a dielectrophoretic force to the light emitting devices 300 using a dielectrophoresis scheme during a manufacturing process.

However, during the manufacturing process, it is difficult to apply a ground voltage to the first electrodes 210 by driving the thin film transistors.

Therefore, in the manufactured display device, the first electrodes 210 can be spaced apart at predetermined intervals in a first direction (X-axis direction), but during the manufacturing process, the first electrodes 210 can be not disconnected in a first direction (X-axis direction) and n be extended and can be disposed to extend long.

For this reason, the first electrodes 210 can be connected to the first floating line FL1 and the second floating line FL2 during the manufacturing process. Therefore, the first electrodes 210 can receive a ground voltage through the first floating line FL1 and the second floating line FL2. Accordingly, by disconnecting the first electrodes 210 after aligning the light emitting devices 300 using a dielectrophoresis scheme during the manufacturing process, the first electrodes 210 can be spaced apart at predetermined intervals in the first direction (X-axis direction).

Meanwhile, the first floating line FL1 and the second floating line FL2 are lines for applying a ground voltage during a manufacturing process, and no voltage can be applied in the manufactured display device. Alternatively, the ground voltage can be applied to the first floating line FL1 and the second floating line FL2 to prevent static electricity in the manufactured display device.

FIG. 6 is a plan view showing pixels of the display area of FIG. 5 in detail.

Referring to FIG. 6, the pixel PX can comprise a first sub-pixel PX1, a second sub-pixel PX2, and a third sub-pixel PX3. The first sub-pixel PX1, the second sub-pixel PX2, and the third sub-pixel PX3 of each of the pixels PX can be arranged in a matrix form in regions defined by the intersection structure of the scan lines Sk and the data lines Dj, Dj+1, Dj+2, and Dj+3.

The scan lines Sk can extend long in a first direction (X-axis direction), and the data lines Dj, Dj+1, Dj+2, and Dj+3 can extend long in the second direction (Y-axis direction) crossing the first direction (X-axis direction).

Each of the first sub-pixel PX1, the second sub-pixel PX2, and the third sub-pixel PX3 can comprise a first electrode 210, a second electrode 220, and a plurality of light emitting devices 300. The first electrode 210 and the second electrode 220 can be electrically connected to the light emitting devices 300 and can receive voltages to emit light of the light emitting device 300.

The first electrode 210 of any one sub-pixel among the first sub-pixel PX1, the second sub-pixel PX2, and the third sub-pixel PX3 can be spaced apart from the first electrode 210 of sub-pixel adjacent to the one sub-pixel. For example, the first electrode 210 of the first sub-pixel PX1 can be spaced apart from the first electrode 210 of the second sub-pixel PX2 adjacent thereto. Also, the first electrode 210 of the second sub-pixel PX2 can be spaced apart from the first electrode 210 of the third sub-pixel PX3 adjacent thereto. Also, the first electrode 210 of the third sub-pixel PX3 can be spaced apart from the first electrode 210 of the first sub-pixel PX1 adjacent thereto.

In contrast, the second electrode 220 of any one sub-pixel among the first sub-pixel PX1, the second sub-pixel PX2, and the third sub-pixel PX3 can be connected to the second electrode 220 of sub-pixel adjacent to the one sub-pixel. For example, the second electrode 220 of the first sub-pixel PX1 can be connected to the second electrode 210 of the adjacent second sub-pixel PX2. Also, the second electrode 220 of the second sub-pixel PX2 can be connected to the second electrode 220 of the third sub-pixel PX3 adjacent thereto. Also, the second electrode 220 of the third sub-pixel PX3 can be connected to the second electrode 220 of the first sub-pixel PX1 adjacent thereto.

In addition, during the manufacturing process, the first electrode 210 and the second electrode 220 can be used to form an electric field in each of the first sub-pixel PX1, the second sub-pixel PX2, and the third sub-pixel PX3 to align the light emitting device 300. Specifically, the light emitting devices 300 can be aligned by applying a dielectrophoresis force to the light emitting devices 300 using a dielectrophoresis scheme during the manufacturing process. An electric field is formed by the voltage applied to the first electrode 210 and the second electrode 220, and a dielectrophoretic force is formed by the electric field such that the dielectrophoretic force can be applied to the light emitting device 300.

The first electrode 210 is an anode electrode connected to the second conductivity type semiconductor layer of the light emitting devices 300, and the second electrode 220 is a cathode electrode connected to the first conductivity type semiconductor layer of the light emitting devices 300. The first conductivity type semiconductor layer of the light emitting devices 300 can be an n-type semiconductor layer, and the second conductivity type semiconductor layer can be a p-type semiconductor layer. However, the present invention is not limited thereto, and the first electrode 210 can be a cathode electrode and the second electrode 220 can be an anode electrode.

The first electrode 210 can comprise a first electrode stem 210S extending long in a first direction (X-axis direction) and at least one first electrode branch 210B branching from the first electrode stem 210S in a second direction (Y-axis direction). The second electrode 220 can comprise a second electrode stem 220S extending long in a first direction (X-axis direction) and at least one second electrode branch 220B branching from the second electrode stem 220S in a second direction (Y-axis direction).

The first electrode stem 210S can be electrically connected to the thin film transistor 120 through the first electrode contact hole CNTD.

For this reason, the first electrode stem 210S can receive a predetermined driving voltage through the thin film transistor 120. The thin film transistor 120 to which the first electrode stem 210S is connected can be the driving transistor DT shown in FIG. 4.

The second electrode stem 220S can be electrically connected to the low potential auxiliary wire 161 through the second electrode contact hole CNTS.

Accordingly, the second electrode stem 220S can receive a low potential voltage of the low potential auxiliary wire 161. In FIG. 6, the second electrode stem 220S can be connected to the low potential auxiliary wire 161 through the second electrode contact hole CNTS in each of the first sub-pixel PX1, the second sub-pixel PX2, and the third sub-pixel PX3 of the pixel PX, but the present invention is not limited thereto. For example, the second electrode stem 220S can be connected to the low potential auxiliary wire 161 through the electrode contact hole CNTS in any one of the first sub-pixel PX1, the second sub-pixel PX2, and the third sub-pixel PX3 of the pixel PX. Alternatively, as shown in FIG. 5, since the second electrode stem 220S is connected to the low potential voltage line VSSL of the non-display area NDA, it may not be connected to the low potential auxiliary line 161. That is, the second electrode contact hole CNTS can be omitted.

The first electrode stem 210S of one sub-pixel can be disposed parallel to the first electrode stem 210S of sub-pixel adjacent to the one sub-pixel in a first direction (X-axis direction) in a first direction (X-axis direction). For example, the first electrode stem 210S of the first sub-pixel PX1 is disposed parallel to the first electrode stem 210S of the second sub-pixel PX2 in the first direction (X-axis direction). The first electrode stem 210S of the second sub-pixel PX2 is disposed parallel to the first electrode stem 210S of the third sub-pixel PX3 in the first direction (X-axis direction). The first electrode stem 210S of the third sub-pixel PX3 can be disposed parallel to the first electrode stem 210S of the first sub-pixel PX1 in the first direction (X-axis direction). This is because the first electrode stems 210S were connected as one during the manufacturing process, and then disconnected through a laser process after the light emitting devices 300 were aligned.

The second electrode branch 220B can be disposed between the first electrode branch 210B. The first electrode branches 210B can be symmetrically disposed with respect to the second electrode branches 220B. In FIG. 6, each of the first sub-pixel PX1, the second sub-pixel PX2, and the third sub-pixel PX3 of the pixel PX includes two first electrode branches 220B, but the present invention is not limited thereto. For example, each of the first sub-pixel PX1, the second sub-pixel PX2, and the third sub-pixel PX3 of the pixel PX can comprise three or more first electrode branches 220B.

In addition, in FIG. 6, each of the first sub-pixel PX1, the second sub-pixel PX2, and the third sub-pixel PX3 of the pixel PX includes one second electrode branch 220B, but the present invention is not limited thereto. For example, when each of the first sub-pixel PX1, the second sub-pixel PX2, and the third sub-pixel PX3 of the pixel PX includes a plurality of second electrode branches 220B, the first electrode branch 210B can be disposed between the second electrode branch 220B. That is, in each of the first sub-pixel PX1, the second sub-pixel PX2, and the third sub-pixel PX3 of the pixel PX, the first electrode branch 210B, the second electrode branch 220B, the first electrode branch 210B and the second electrode branch 220B can be sequentially arranged in the first direction (X-axis direction).

The plurality of light emitting devices 300 can be disposed between the first electrode branch 210B and the second electrode branch 220B. One end of at least one light emitting device 300 among the plurality of light emitting devices 300 is disposed to overlap the first electrode branch 210B, and the other end is disposed to overlap the second electrode branch 220B. A second conductivity type semiconductor layer, which is a p-type semiconductor layer, can be disposed at one end of each of the plurality of light emitting devices 300, and a first conductivity type semiconductor layer, which is an n-type semiconductor layer, can be disposed at the other end, but is not limited thereto. For example, a first conductivity type semiconductor layer, which is an n-type semiconductor layer, can be disposed at one end of the plurality of light emitting devices 300, and a second conductivity type semiconductor layer, which is a p-type semiconductor layer, can be disposed at the other end.

The plurality of light emitting devices 300 can be disposed substantially side by side in the first direction (X-axis direction). The plurality of light emitting devices 300 can be spaced apart from each other in the second direction (Y-axis direction). In this case, the spacing interval between the plurality of light emitting devices 300 can be different from each other. For example, some of the plurality of light emitting devices 300 can be adjacently disposed to form one group, and the remaining light emitting devices 300 can be adjacently disposed to form another group.

A connection electrode 260 can be disposed on the first electrode branch 210B and the second electrode branch 220B, respectively. The connection electrodes 260 can be disposed to extend long in the second direction (Y-axis direction) and spaced apart from each other in the first direction (X-axis direction). The connection electrode 260 can be connected to one end of at least one light emitting device 300 among the light emitting devices 300. The connection electrode 260 can be connected to the first electrode 210 or the second electrode 220.

The connection electrode 260 can comprise a first connection electrode 261 disposed on the first electrode branch 210B and connected to one end of at least one light emitting device 300 of the light emitting devices 300, and a second connection electrode 262 disposed on the branch portion 220B and connected to one end of at least one light emitting device 300 of the light emitting devices 300. For this reason, the first connection electrode 261 serves to electrically connect the plurality of light emitting devices 300 to the first electrode 210, and the second connection electrode 262 serves to electrically connect the plurality of light emitting devices 300 to the second electrode 220.

A width of the first connection electrode 261 in the first direction (X-axis direction) can be greater than a width of the first electrode branch 210B in the first direction (X-axis direction). Also, the width of the second connection electrode 262 in the first direction (X-axis direction) can be greater than the width of the second electrode branch 220B in the first direction (X-axis direction).

For example, each end of the light emitting devices 300 is disposed on the first electrode branch 210B of the first electrode 210 and the second electrode branch 220B of the second electrode 220, but due to an insulating layer (not shown) formed on the first electrode 210 and the second electrode 220, the light emitting device 300 may not be electrically connected to the first electrode 210 and the second electrode 220. Accordingly, portions of a side surface and/or an upper surface of the light emitting device 300 can be electrically connected to the first connection electrode 261 and the second connection electrode 262, respectively.

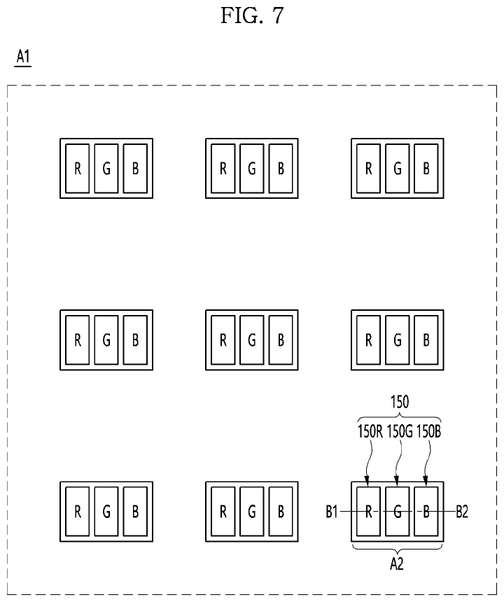

FIG. 7 is an enlarged view of a first panel area in the display device of FIG. 2.

Referring to FIG. 7, a display device 100 of the embodiment can be manufactured by mechanically and electrically connecting a plurality of panel regions such as the first panel region A1 by tiling.

The first panel region A1 can include a plurality of light emitting devices 150 disposed for each unit pixel (PX in FIG. 3). The light emitting device 150 can be the light emitting device 300 of FIG. 6.

The light emitting device 150 can comprise, for example, a red light emitting device 150R, a green light emitting device 150G, and a blue light emitting device 150B. For example, the unit pixel PX can comprise a first sub-pixel PX1, a second sub-pixel PX2, and a third sub-pixel PX3. For example, a plurality of red light emitting devices 150R are disposed in the first sub-pixel PX1, a plurality of green light emitting devices 150G are disposed in the second sub-pixel PX2, and a plurality of blue light emitting devices 150B can be disposed in the third sub-pixel PX3. The unit pixel PX can further comprise a fourth sub-pixel in which no light emitting device is disposed, but is not limited thereto.

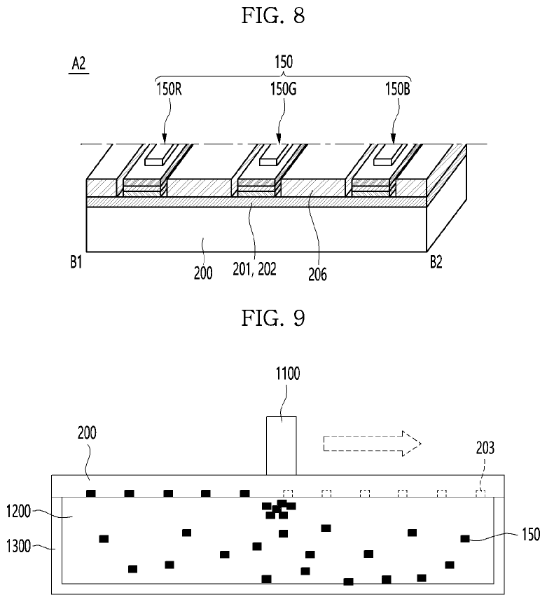

FIG. 8 is an enlarged view of the area A2 of FIG. 7.

Referring to FIG. 8, the display device 100 according to an embodiment can comprise a substrate 200, wiring lines 201 and 202, an insulating layer 206, and a plurality of semiconductor light emitting devices 150.

The wiring line can comprise a first wiring line 201 and a second wiring line 202 spaced apart from each other.

The semiconductor light emitting device 150 can comprise a red semiconductor light emitting device 150R, a green semiconductor light emitting device 150G, and a blue semiconductor light emitting device 150B to form a sub-pixel, but is not limited thereto. In other words, red and green can be implemented by providing a red phosphor and a green phosphor.

The substrate 200 can be formed of glass or polyimide. In addition, the substrate 200 can comprise a flexible material such as polyethylene naphthalate (PEN) or polyethylene terephthalate (PET). In addition, the substrate 200 can be a transparent material, but is not limited thereto.

The insulating layer 130 can comprise an insulating and flexible material such as polyimide, PEN, PET, or the like, and can be integrally formed with the substrate 200 to form a single substrate.

The insulating layer 206 can be a conductive adhesive layer having adhesiveness and conductivity. The conductive adhesive layer can have ductility to enable a flexible function of the display device. For example, the insulating layer 206 can be an anisotropic conductive film (ACF). For example, the insulating layer 206 can a conductive adhesive layer such as an anisotropic conductive medium or a solution containing conductive particles. The conductive adhesive layer can be a layer that is electrically conductive in a direction perpendicular to the thickness but electrically insulating in a direction horizontal to the thickness.

The insulating layer 206 can comprise an assembly hole 203 into which the semiconductor light emitting device 150 is inserted. Therefore, during self-assembly, the semiconductor light emitting device 150 can be easily inserted into the assembly hole 203 of the insulating layer 206.

FIG. 9 is a view showing an example in which a light emitting device according to an embodiment is assembled to a substrate by a self-assembly method.

Referring to FIG. 9, an example in which the light emitting device 150R according to the embodiment is assembled to the substrate 200 by a self-assembly method using an electromagnetic field will be described.

In FIGS. 8 and 9, the substrate 200 can be a panel substrate of a display device or a temporary donor substrate for transfer.

In the following description, the substrate 200 will be described as a panel substrate of a display device, but the embodiment is not limited thereto.

The substrate 200 can be formed of glass or polyimide. In addition, the substrate 200 can comprise a flexible material such as polyethylene naphthalate (PEN) or polyethylene terephthalate (PET). In addition, the substrate 200 can be a transparent material, but is not limited thereto.

Referring to FIG. 9, a light emitting device 150R can be put into a chamber 1300 filled with a fluid 1200. The fluid 1200 can be water such as a deionized water, but is not limited thereto. A chamber can also be called a water bath, container, vessel, etc.

After that, the substrate 200 can be disposed on the chamber 1300, according to the embodiment, the substrate 200 can be put into the chamber 1300.

A pair of wiring lines 201 and 202 corresponding to each of the light emitting devices 150R to be assembled can be formed on the substrate 200.

The wiring lines 201 and 202 can be formed of transparent electrodes (ITO) or can comprise metal having excellent electrical conductivity. For example, the wiring lines 201 and 202 can be formed of at least one or an alloy thereof titanium (Ti), chromium (Cr), nickel (Ni), aluminum (Al), platinum (Pt), gold (Au), tungsten (W), molybdenum (Mo).

The wiring lines 201 and 202 can function as a pair of assembly electrodes that fix the light emitting device 150R assembled into the assembly hole 203 on the substrate 200 by emitting an electric field as voltage is applied thereto.

The distance between the wiring lines 201 and 202 is smaller than the width of the light emitting device 150R and the width of the assembly hole 203 so that the assembly position of the light emitting device 150R using an electric field can be fixed more precisely.

An insulating member 206 can be formed on the wiring lines 201 and 202 to protect the wiring lines 201 and 202 from the fluid 1200 and prevent current flowing through the wiring lines 201 and 202 from leaking. The insulating member 206 can be formed of a single layer or multiple layers of an inorganic insulator such as silica or alumina or an organic insulator.

In addition, the insulating member 206 can comprise an insulating and flexible material such as polyimide, PEN, PET, or the like, and can be integrally formed with the substrate 200 to form a single substrate.

The insulating member 206 can be an adhesive insulating layer or a conductive adhesive layer having conductivity. The insulating member 206 can have flexibility and enable a flexible function of the display device.

A barrier rib 200S can be formed on an upper portion of the insulating member 206. A portion of the barrier rib 200S can be positioned on an upper side of the wiring lines 201 and 202.

For example, when forming the substrate 200, some of the barrier ribs formed on an upper side of the insulating member 206 can be removed, so that an assembly hole 203 in which each of the light emitting devices 150R is assembled to the substrate 200 can be formed. A second pad electrode 222 can be formed between the barrier rib 200S and the insulating member 206 to apply power to the light emitting device 150R.

The assembly holes 203 to which the light emitting devices 150R are coupled can be formed in the substrate 200, and a surface on which the assembly holes 203 are formed can contact the fluid 1200. The assembly hole 203 can guide the accurate assembly position of the light emitting device 150R.

Meanwhile, the assembly hole 203 can have a shape and size corresponding to a shape of the light emitting device 150R to be assembled at the corresponding position. Accordingly, it is possible to prevent assembly of other light emitting devices or assembly of a plurality of light emitting devices into the assembly hole 203.

Referring back to FIG. 9, after the substrate 200 is disposed, the assembly device 1100 comprising a magnetic material can move along the substrate 200. As the magnetic material, for example, a magnet or an electromagnet can be used. The assembly device 1100 can move while in contact with the substrate 200 in order to maximize the area of the magnetic field into the fluid 1200. Depending on the embodiment, the assembly device 1100 can comprise a plurality of magnetic bodies or can comprise a magnetic body having a size corresponding to that of the substrate 200. In this case, the moving distance of the assembling device 1100 can be limited within a predetermined range.

Due to the magnetic field generated by the assembly device 1100, the light emitting device 150R in the chamber 1300 can move toward the assembly device 1100.

While moving toward the assembly device 1100, the light emitting device 150R can enter the assembly hole 203 and come into contact with the substrate 200.

At this time, the electric field applied by the wiring lines 201 and 202 formed on the substrate 200 prevents the light emitting device 150R contacting the substrate 200 from being separated by the movement of the assembly device 1100.

That is, since the self-assembly method using the electromagnetic field described above can drastically shorten the time required for assembling each of the light emitting devices 150R to the substrate 200, a large-area high-pixel display can be implemented more quickly and economically.

A solder layer 225 is further formed between the light emitting device 150R assembled on the assembly hole 203 of the substrate 200 and the second pad electrode 222 to improve the bonding strength of the light emitting device 150R.

Thereafter, the first pad electrode 221 can be connected to the light emitting device 150R to apply power.

Next, a molding layer 230 can be formed on the barrier rib 200S and the assembly hole 203 of the substrate 200. The molding layer 230 can be a transparent resin or a resin containing a reflective material or a scattering material.

Hereinafter, a light emitting device and a display device capable of always emitting light regardless of assembly direction will be described with reference to various embodiments.

### First Embodiment

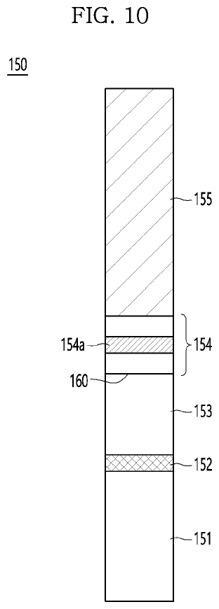

FIG. 10 is a cross-sectional view illustrating a light emitting device according to a first embodiment.

Referring to FIG. 10, the light emitting device 150 according to the first embodiment can comprise a first conductivity type semiconductor layer 151, an active layer 152, a second conductivity type semiconductor layer 153, and at least one or more electrode layers 154, and an insulating layer 155. The active layer 152 can be referred to as a light emitting layer or a light emitting region.

Although a rod light emitting device is shown as the light emitting device 150 according to the first embodiment in the drawing, various light emitting devices are possible as an embodiment of the present invention. For example, a micro light emitting device, a disk light emitting device, a cylindrical light emitting device, or the like can be used as the light emitting device according to the first embodiment.

The cross section of the light emitting device 150 according to the first embodiment can have various shapes, such as circular, triangular, rectangular, polygonal, or the like.

In the first embodiment, the first conductivity type semiconductor layer 151 can be positioned on one side of the light emitting device 150 and the insulating layer 155 can be positioned on the other side of the light emitting device 150. For example, the second conductivity type semiconductor layer 153 can be positioned in the central region of the light emitting device 150 according to the first embodiment. For example, at least one or more electrode layers 154 among the at least one or more electrode layers 154 can be positioned in the central region of the light emitting device 150 according to the first embodiment.

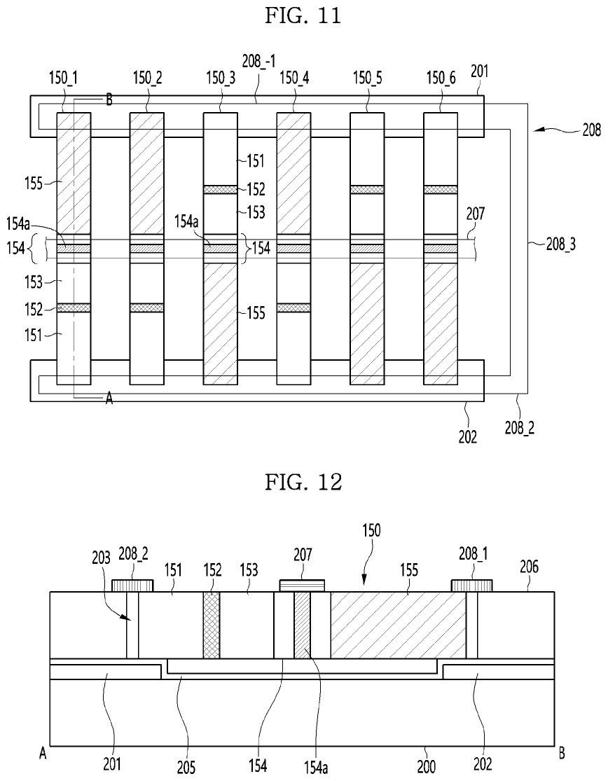

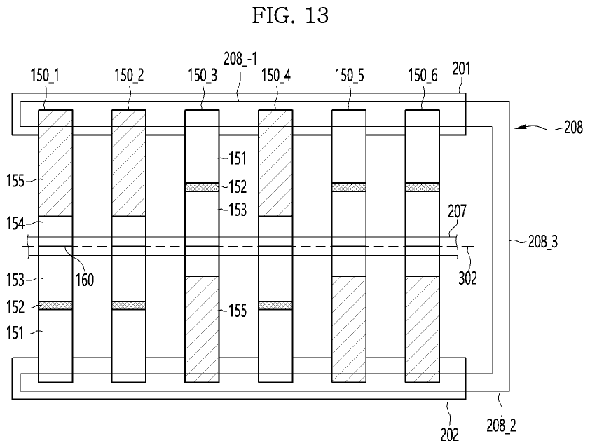

For example, the total thickness of the first conductivity type semiconductor layer 151 and the active laver 152 can be the same as that of the insulating layer 155 so that as shown in FIG. 11, the electrode layer 154 of the light emitting device 150 can be positioned in the central area. For example, the total thickness of the first conductivity type semiconductor layer 151 and the active layer 152 can be the same as that of the insulating layer 155 so that the second conductivity type semiconductor layer 153 can be positioned in the central region of the light emitting device 150. For example, as shown in FIG. 13 by adjusting the thickness of each of the first conductivity type semiconductor layer 151 and/or the insulating layer 155, the boundary 160 between the second conductivity type semiconductor layer 153 and the electrode layer 154 can be positioned in the central region of the light emitting device 150.

For example, the total thickness of the first conductivity type semiconductor layer 151, the active layer 152, and the second conductivity type semiconductor layer 153 can be the same as that of the insulating layer 155 so that the electrode layer 154 can be positioned in the central region of the light emitting device 150.

When the light emitting devices 150 according to the first embodiment configured as described above are assembled to the display device along one direction, the light emitting devices 150 can always emit light regardless of the assembly direction. Therefore, it is possible to implement a high-brightness display by preventing the occurrence of defective light emitting devices, reducing costs and improving luminance. This will be described later with reference to FIGS. 11 to 15.

Here, the assembly direction can mean a direction in which, for example, the first conductivity type semiconductor layer 151 of the light emitting device 150 can be positioned on the second wiring line 202 shown in FIG. 11, and the insulating layer of the light emitting device 150 155 can be positioned on the first wiring line 201 shown in FIG. 11. When the light emitting device 150 having such directivity is assembled to a display device, the light emitting device 150 can emit light.

When the light emitting device 150 is disposed in the opposite assembly direction, that is, for example, the first conductivity type semiconductor layer 151 of the light emitting device 150 is positioned on the first wiring line 201 shown in FIG. 11, and the insulating layer 155 of the light emitting device 150 is positioned on the second wiring line 202 shown in FIG. 11, as the assembly direction is defective, the corresponding light emitting device 150 can be a defective light emitting device that does not emit light. Therefore, it is very important to assemble light emitting devices in a display device in an assembly direction in order to prevent defects of light emitting devices and improve luminance.

For example, the first conductivity type semiconductor layer 151, the active layer 152, and the second conductivity type semiconductor layer 153 can be grown using deposition equipment, for example, MOCVD equipment. At least one or more electrode layers 154 can be formed using, for example, sputter equipment.

After the first conductivity type semiconductor layer 151, the active layer 152, the second conductivity type semiconductor layer 153, at least one or more electrode layers 154, and the insulating layer 155 are formed on the substrate for growth, for example, the substrate for growth can be removed using a laser lift-off (LLO) process. The substrate for growth can be a sapphire substrate or a semiconductor substrate, but is not limited thereto.

The first conductivity type semiconductor layer 151 can be formed on the substrate for growth. Before the first conductivity type semiconductor layer 151 is formed, a buffer layer (not shown) can be formed to alleviate lattice mismatch between the substrate for growth and the first conductivity type semiconductor layer 151.

The first conductivity type semiconductor layer 151 can be provided as a compound semiconductor. The first conductivity type semiconductor layer 151 can be provided as, for example, a group 2-6 compound semiconductor or a group 3-5 compound semiconductor. For example, the first conductivity type semiconductor layer 151 can be doped with an n-type dopant such as Si, Ge, Sn, Se, Te, etc.

The active layer 152 can be formed on the first conductivity type semiconductor layer 151. The active layer 152 can generate light of a specific wavelength band by recombination of first carriers (e.g. electrons) provided from the first conductivity type semiconductor layer 151 and second carriers (e.g. holes) provided from the second conductivity type semiconductor layer 153. The active layer 152 can have any one or more of a single well structure, a multi-well structure, a quantum dot structure, or a quantum line structure. The active layer 152 can be provided as a compound semiconductor. The active layer 152 can be provided with, for example, a group 2-6 or group 3-5 compound semiconductor. When the active layer 152 is provided in a multi-well structure, the active layer 152 can be provided by stacking a plurality of barrier layers and a plurality of well layers.

The second conductivity type semiconductor layer 153 can be formed on the active layer 152. The second conductivity type semiconductor layer 153 can be provided as a compound semiconductor. The second conductivity type semiconductor layer 153 can be provided as, for example, a group 2-6 compound semiconductor or a group 3-5 compound semiconductor. For example, the second conductivity type semiconductor layer 153 can be doped with a p-type dopant such as Mg, Zn, Ca, Sr, Ba, etc.

The electrode layer 154 can be formed on the second conductivity type semiconductor layer 153. For example, the electrode layer 154 can more smoothly supply current to the second conductivity type semiconductor layer 153. Since the second conductivity type semiconductor layer 153 includes a p-type dopant and has a relatively smaller thickness than that of the first conductivity type semiconductor layer 151, the amount of holes generated in the second conductivity type semiconductor layer 153 can be smaller than the amount of electrons generated in the first conductivity type semiconductor layer 151. Therefore, in order to increase the number of holes generated in the second conductivity type semiconductor layer 153, current needs to be smoothly supplied. To this end, the electrode layer 154 can be formed on the second conductivity type semiconductor layer 153. Although not shown, at least one or more electrode layers 154 can be formed below the first conductivity type semiconductor layer 151 to more smoothly supply current to the first conductivity type semiconductor layer 151.

For example, the electrode layer 154 can comprise a plurality of metal layers comprising different metals. The electrode layer 154 can comprise a magnetic layer 154a. For example, the magnetic layer 154a can be a metal such as Ni.

As shown in FIG. 9, when the self-assembly is performed, the light emitting devices 150 can be moved by the magnet according to the movement of the magnet, and the light emitting device 150 can be assembled in the assembly hole 203 at a specific position of the substrate 200. The metal of the light emitting device 150 can comprise a magnetic layer 154a so that the light emitting device 150 can be guided by a magnet.

Although one magnetic layer 154a is shown in the drawing, two or more magnetic layers can be provided. Although not shown in the drawings, a magnetic layer 154a can be formed below the second conductivity type semiconductor layer 153.

An insulating layer 155 can be formed on the electrode layer 154. The insulating layer 155 can be formed on the other side opposite to the first conductivity type semiconductor layer 151. The first conductivity type semiconductor layer 151 can be formed on one side of the light emitting device 150. That is, the first conductivity type semiconductor layer 151 and the insulating layer 155 can be formed on both sides of the light emitting device 150. For example, the insulating layer 155 can be made of an inorganic material such as SiNx, but is not limited thereto.

[Manufacturing process]

A manufacturing process of the light emitting device 150 according to the first embodiment will be described.

First, the first conductivity type semiconductor layer 151, the active layer 152, and the second conductivity type semiconductor layer 153 can be grown on a substrate for growth using MOCVD equipment. After that, at least one or more electrode layers 154 can be formed on the second conductive semiconductor layer 153 using sputter equipment. After that, an insulating layer 155 can be formed on the electrode layers 154.

Thereafter, after patterning the insulating layer 155 and the electrode layer 154 using an etching process, mesa etching can be performed. That is, the second conductivity type semiconductor layer 153, the active layer 152, and the first conductivity type semiconductor layer 151 can be etched using a separate mask or the patterned insulating layer 155 as a mask. Then, a plurality of light emitting devices 150 can be manufactured on the substrate for growth by applying laser to the substrate for growth using the LLO process and removing the substrate for growth.

The above manufacturing process is described as an example, and various modification processes can be possible.

Hereinafter, an assembly example of the light emitting device 150 according to the first embodiment will be described with reference to FIGS. 11 to 15

FIG. 11 is a plan view illustrating a first example of a display device having a light emitting device according to the first embodiment. FIG. 12 is a cross-sectional view taken along line A-B of FIG. 11.

Referring to FIGS. 10 to 12, a plurality of light emitting devices 150_1 to 150_6 manufactured according to the first embodiment can be assembled to a substrate 200. The plurality of light emitting devices 150_1 to 150_6 can be arranged along one direction, for example, a horizontal direction with reference to FIG. 11. The plurality of light emitting devices 150_1 to 150_6 can be the light emitting device 150 shown in FIG. 10.

The display device can comprise a substrate 200, a plurality of first wiring lines 201, a plurality of second wiring lines 202, a first insulating member 205, a second insulating member 206, a plurality of light emitting devices 150_1 to 150_6), a first electrode line 207 and a second electrode line 208. The second insulating member 206 can be the insulating member 206 shown in FIG. 8.

FIG. 12 illustrates the light emitting device 150_1 shown in one assembly hole 203, but in the display device according to the embodiment, the light emitting devices 150_1 to 150_6 can be disposed in each of a plurality of assembly holes 203.

That is, as shown in FIG. 3, the display device of the embodiment can comprise a plurality of pixels PX, and each pixel PX can comprise, for example, a first sub-pixel PX1, a second sub-pixel PX2, and a third sub-pixel PX3. A plurality of light emitting devices 300 can be included in each of the first sub-pixel PX1, the second sub-pixel PX2, and the third sub-pixel PX3. Accordingly, each of the sub-pixels PX1, PX2, and PX3 can be provided with an assembly hole 203 for assembling each of the plurality of light emitting devices 300.

For example, each of the first pad electrode 210 and the second pad electrode 220 of FIG. 3 can be the first electrode line 207 and the second electrode line 208 shown in FIGS. 11 and 12. Although not shown, the display device of FIG. 3 can also comprise the first wiring line 201 and the second wiring line 202 shown in FIG. 12.

FIGS. 11 and 12 illustrate an assembly hole 203 for assembling one light emitting device 300 included in any sub-pixel among the first to third sub-pixels PX1, PX2, and PX3 shown in FIG. 3.

Referring to FIGS. 11 and 12, the light emitting devices 150_1 to 150_6 can be assembled by the dielectrophoretic force formed by the first wiring line 201 and the second wiring line 202. That is, a dielectrophoretic force can be generated between the first wiring line 201 and the second wiring line 202 by the voltage applied to the first wiring line 201 and the second wiring line 202. When the plurality of light emitting devices 150_1 to 150_6 are dropped onto the substrate 200, the plurality of light emitting devices 150_1 to 150_6 can be assembled and fixed to the assembly hole 203 by the dielectrophoretic force generated between the first wiring line 201 and the second wiring line 202.

The light emitting devices 150_1 to 150_6 can comprise a plurality of red light emitting devices disposed in the first sub-pixel PX1, a plurality of green light emitting devices disposed in the second sub-pixel PX2, and a plurality of green light emitting devices disposed in the third sub-pixel PX3.

Referring to FIGS. 10 to 12, the substrate 200 can be a base substrate for forming the first wiring line 201, the second wiring line 202, the first insulating member 205, the second insulating member 206, the first electrode line 207 and the second electrode line 208.

For example, the substrate 200 can have a rigid property. For example, the substrate 200 can have a flexible property. For example, the substrate 200 can have a stretchable property. For example, the substrate 200 can have a rollable property. In addition, the substrate 200 can have various properties such as strength, warpage, etc.

For example, the substrate 200 can be glass. For example, the substrate 200 can be a resin material. For example, the substrate 200 can be a plastic material. In addition, the substrate 200 can be formed of various materials.

In the display device according to the embodiment, the substrate 200 can be a single substrate. In the display device according to the embodiment, the substrate 200 can comprise a plurality of substrates connected to each other. In the display device according to the embodiment, the substrate 200 can comprise at least one or more layers.

The first wiring line 201 and the second wiring line 202 can be disposed on the substrate 200. The first wiring line 201 and the second wiring line 202 can be spaced apart from each other, can face each other, and can be parallel to each other, but are not limited thereto.

The first wiring line 201 and the second wiring line 202 can be made of a metal. The first wiring line 201 and the second wiring line 202 can generate dielectrophoretic force in a direction perpendicular to the longitudinal direction of each of the first wiring line 201 and the second wiring line 202 by a voltage. When the light emitting devices 150_1 to 150_6 are placed between the first wiring line 201 and the second wiring line 202, the light emitting devices 150_1 to 150_6 can be assembled and fixed to the first wiring line 201 and the second wiring line 202 by dielectrophoretic force.

The first insulating member 205 can be disposed on the entire area of the substrate 200. For example, the first insulating member 205 can be disposed on the first wiring line 201 and the second wiring line 202. The first insulating member 205 can protect the first wiring line 201 and the second wiring line 202 and prevent a short circuit between the first wiring line 201 and the second endorsement line. The first insulating member 205 can be made of an inorganic material such as SiOx, but is not limited thereto.

The second insulating member 206 can be disposed on the first insulating member 205. The second insulating member 206 can be made of an organic material, but is not limited thereto.

The second insulating member 206 can be a planarization layer. That is, the second insulating member 206 can be formed to be relatively thick and have a flat upper surface. Accordingly, the step formed by the first wiring line 201 and the second wiring line 202 is removed so that a member can be easily and accurately formed on the second insulating member 206 by a post-process during a later process.

Meanwhile, the second insulating member 206 can comprise a plurality of assembly holes 203. The light emitting devices 150_1 to 150_6 can be assembled into each of the plurality of assembly holes 203. For example, the second insulating member 206 can be formed on the first insulating member 205, and a plurality of assembly holes 203 can be formed by locally removing the second insulating member 206 to have the same size as or a size greater than the size of the light emitting devices 150_1 to 150_6.

The Light emitting devices 150_1 to 150_6 can be assembled to each of the plurality of assembly holes 203.

For example, as shown in FIG. 9, the fluid 1200 is filled in the chamber 100, and a large amount of light emitting devices 150 can be accommodated in the fluid 1200. After the substrate 200 is positioned on an upper side of the chamber 100, as the assembly device 1100 comprising a plurality of magnetic materials on the substrate 200 moves or rotates in one direction, the light emitting device 150 accommodated in the fluid 1200 of the chamber 100 can be moved along the moving direction of the assembly device 1100 and guided to the assembly device 1100. The light emitting devices 150 guided in this way can be inserted into the corresponding assembly hole 203 of the substrate 200 positioned on the plurality of magnetic bodies of the assembly device 1100. Accordingly, as shown in FIGS. 11 and 12, the plurality of light emitting devices 150_1 to 150_6 can be aligned between the first wiring line 201 and the second wiring line 202.

A dielectrophoretic force can be generated by a voltage applied between the first wiring line 201 and the second wiring line 202 before or simultaneously with the movement of the assembly device 1100. The light emitting devices 150_1 to 150_6 inserted into the assembly hole 203 can be assembled and fixed to the assembly hole 203 by the dielectrophoretic force formed between the first wiring line 201 and the second wiring line 202.

Accordingly, the plurality of light emitting devices 150_1 to 150_6 can be arranged along the horizontal direction as shown in FIG. 11. Each of the plurality of light emitting devices 150_1 to 150_6 shown in FIG. 11 can be assembled into the corresponding assembly hole 203 of the second insulating member 206.

As shown in FIG. 11, the major axes of the light emitting devices 150_1 to 150_6 can be arranged to coincide with the vertical direction and the minor axes of the light emitting devices 150_1 to 150_6 can be arranged to coincide with the horizontal direction.

As shown in FIG. 12, lower surfaces of the light emitting devices 150_1 to 150_6 assembled in the assembly hole 203 can partially contact the first insulating member 205. Lower surfaces of some regions of each of the light emitting devices 150_1 to 150_6 can be spaced apart from an upper surface of the first insulating member 205 due to a step difference between the first wiring line 101 and the second wiring line 202.

In the drawing, the size of the assembly hole 203 is greater than the size of the light emitting devices 1501 to 150_6 so that both side surfaces of the light emitting devices 150_1 to 150_6 can be spaced apart from an inner surface of the assembly hole 203, but by adjusting the size of the assembly hole 203, both side surfaces of the light emitting devices 150_1 to 150_6 can come into contact with the inner surface of the assembly hole 203.

According to the embodiment, the light emitting devices 150_1 to 150_6 always assembled on the substrate 200 can emit light regardless of the assembly direction. To this end, as described above, one of the second conductivity type semiconductor layer 153 and the electrode layer 154 of the light emitting devices 150_1 to 150_6 can be positioned in the central region of the light emitting devices 150_1 to 150_6.

In addition, as shown in FIG. 11, the first electrode line 207 can be disposed to cross the central region of each of the plurality of light emitting devices 150_1 to 150_6, and the second electrode line 208 can be disposed to cross both side regions of each of the plurality of light emitting devices 150_1 to 150_6.

The second electrode line 208 can comprise a second-first electrode line 208_1 disposed to cross a first side region of each of the plurality of light emitting devices 150_1 to 150_6, a second-second electrode line 2082 disposed to cross a second region of each of the plurality of light emitting devices 150_1 to 150_6, and a connection electrode 208_3 connecting the second-first electrode line 208_1 and the second-second electrode line 208_2. The first side region and the second side region can be located on opposite sides of the light emitting devices 150_1 to 150_6.

The first electrode line 207 and the second electrode line 208 can be disposed on an upper surface of each of the plurality of light emitting devices 150_1 to 150_6. In FIG. 12, the second electrode line 208 is shown as being disposed on a part of the upper surface of the light emitting device 150_1 to 150_6 and a part of the upper surface of the second insulating member 206, but the second electrode line 208 can be disposed on only the part of the upper surface of the light emitting device 150_1 to 150_6.

The first electrode line 207 can contact the electrode layer 154 positioned in the central region of each of the plurality of light emitting devices 1501 to 150_6, and the second electrode line 208 can contact the first conductivity type semiconductor layer 151 and the insulating layer 155 positioned on both side regions of each of the plurality of light emitting devices 150_1 to 150_6.

Accordingly, a first signal can be supplied to the electrode layer 154 positioned in the central region of each of the plurality of light emitting devices 150_1 to 1506 through the first electrode line 207. In addition, a second signal can be supplied to the first conductivity type semiconductor layer 151 positioned on both side regions of each of the plurality of light emitting devices 1501 to 150_6 through the second electrode line 208. Since the insulating layers 155 of the light emitting devices 150_1 to 150_6 are non-conductive, the second signal is not supplied. For example, the first signal can be a positive (+) voltage and the second signal can be a negative (−) voltage.

When the second signal is supplied to the connection electrode 2083, the second signal can be supplied to the first conductivity type semiconductor layer 151 positioned on both side regions of each of the plurality of light emitting devices 150_1 to 150_6 through the second-first electrode line 208_1 and the second-second electrode line 208_2 connected to the connection electrode 208_3.

As shown in FIG. 11, when six light emitting devices 150_1 to 150_6 are assembled on a substrate 200, the first conductive semiconductor layer 151 can contact the second-second electrode line 208_2 of the second electrode line 208, and the insulating layer 155 can contact the second-first electrode line 208_1 of the second electrode line 208 in the first light emitting device 150_1, the second light emitting device 150_2, and the fourth light emitting device 150_4. In the third light emitting device 1503, the fifth light emitting device 150_5, and the sixth light emitting device 150_6, the first conductivity type semiconductor layer 151 can contact the second-first electrode line 208_1 of the second electrode line 208 and the insulating layer 155 can contact the second electrode line 208_2 of the second electrode line 208.

For example, the first signal supplied to the first electrode line 207 can be supplied to the electrode layer 154 positioned in the central region of each of the first to sixth light emitting devices 150_1 to 150_6.

For example, the second signal supplied to the second electrode line 208 can be supplied to the connection electrode 208_3, the second-first electrode line 208_1, and the second-second electrode line 208_2. Therefore, the second signal can be supplied to the first conductivity type semiconductor layer 151 of each of the first light emitting device 150_1, the second light emitting device 150_2, and the fourth light emitting device 150_4. It can be supplied to the conductive semiconductor layer 151. In addition, the second signal can be supplied to the third light emitting device 150_3, the fifth light emitting device 1505, and the sixth light emitting device 150_6 through the second-first electrode line 208_1 of the second electrode line 208.

Therefore, even if the plurality of light emitting devices 150_1 to 150_6 are arranged between the first wiring line 201 and the second wiring line 202 in different assembling directions, the first signal can be supplied to the electrode layer 154 positioned in the central region of each of the plurality of light emitting devices 150_1 to 150_6, and the second signal can be supplied to the first conductivity type semiconductor layer 151 of each of the plurality of light emitting devices 150_1 to 150_6. Thus, all of the plurality of light emitting devices 150_1 to 150_6 can emit light.

That is, the first conductivity type semiconductor layer 151 of each of the first light emitting device 150_1, the second light emitting device 150_2, and the fourth light emitting device 150_4 can be disposed on the second wiring line 202, and the third light emitting device 1503, the fifth light emitting device 150_5, and the sixth light emitting device 150_6 can be disposed on the first wiring line 201.

Even with this layout structure, the second signal can be supplied to the first conductivity type semiconductor layer 151 of each of the first light emitting device 150_1, the second light emitting device 1502, and the fourth light emitting device 1504 disposed on the second wiring line 202. In addition, the second signal can be supplied to the first conductivity type semiconductor layer 151 of each of the third light emitting device 150_3, the fifth light emitting device 150_5 and the sixth light emitting devices 150_6 disposed on the first wiring line 201 through the second-first electrode line 208_1 of the second electrode line 208. That is, even if the assembly directions of the first to sixth light emitting devices 150_1 to 150_6 are different from each other, the first signal or the second signal is always supplied to the first to sixth light emitting devices 150_1 to 150_6, respectively to emit light.

In the related art, about 50% of the number of the light emitting devices assembled on a substrate do not emit light. In contrast, in the embodiment, all of the light emitting devices 150_1 to 150_6 assembled on the substrate can emit light. Therefore, in the embodiment, since there is no defective light emitting device for each pixel, it is possible to significantly reduce costs by preventing waste of defective light emitting devices. In addition, since about 50% of the light emitting devices for each pixel can emit more light than in the related art, the luminance is remarkably improved, enabling a high luminance display. In addition, since defective light emitting devices do not occur for each pixel, when a uniform number of the light emitting devices is assembled in each pixel, a uniform luminance can be secured and more precise luminance control is possible.

Meanwhile, although not shown, a space other than the light emitting devices 150_1 to 150_6 in the assembly hole 203 can be filled with a separate insulating member so that the second electrode line 208 can be more easily formed. For example, epoxy can be used as an insulating member, but is not limited thereto. Since the upper surface of the insulating member has the same position as the upper surface of the second insulating member 206 and/or the upper surface of the light emitting devices 150_1 to 1506, the second electrode line 208 can be easily formed.

FIG. 13 is a plan view illustrating a second example of a display device having a light emitting device according to the first embodiment.

As shown in FIG. 13, a portion of the first electrode line 207 can be disposed to cross the central region of each of the plurality of light emitting devices 150_1 to 150_6, and the second electrode line 208 can be disposed to cross both side regions of each of the plurality of light emitting devices 150_1 to 150_6.

The second electrode line 208 can comprise a second-first electrode line 208_1 disposed to cross a first side region of each of the plurality of light emitting devices 150_1 to 150_6, a second-second electrode line 2082 disposed to cross the second side region of each of the plurality of light emitting devices 150_1 to 150_6, and a connection electrode 208_3 connecting the second-first electrode line 208_1 and the second-second electrode line 208_2. The first side region and the second side region can be located on opposite sides of the light emitting devices 1501 to 150_6.

For example, the first electrode line 207 can contact a portion of the second conductive semiconductor layer 153 and a portion of the electrode layer 154 of each of the plurality of light emitting devices 150_1 to 150_6. In this case, the boundary 160 between the second conductivity type semiconductor layer 153 and the electrode layer 154 can coincide with the center line 302 along the horizontal direction in the first electrode line 207, but is not limited thereto.

For example, as shown in FIG. 13 by adjusting the thickness of each of the first conductivity type semiconductor layer 151 and/or the insulating layer 155, the boundary 160 between the second conductivity type semiconductor layer 153 and the electrode layer 154 can be positioned in the central region of the light emitting devices 150_1 to 150_6. That is, the boundary 160 between the second conductivity type semiconductor laver 153 and the electrode layer 154 can be positioned at the center of the light emitting device 150_1 to 150_6. The center can be a center line or a center point in the center area of the light emitting device 150_1 to 150_6.

Therefore, in the embodiment, since no defective light emitting device exists for each pixel, it is possible to significantly reduce costs by preventing waste of defective light emitting devices. In addition, since about 50% of the light emitting devices for each pixel can emit more light than in the related art, the luminance is remarkably improved, enabling a high luminance display. In addition, since defective light emitting devices do not occur for each pixel, when a uniform number of the light emitting devices is assembled in each pixel, a uniform luminance can be secured and more precise luminance control is possible.

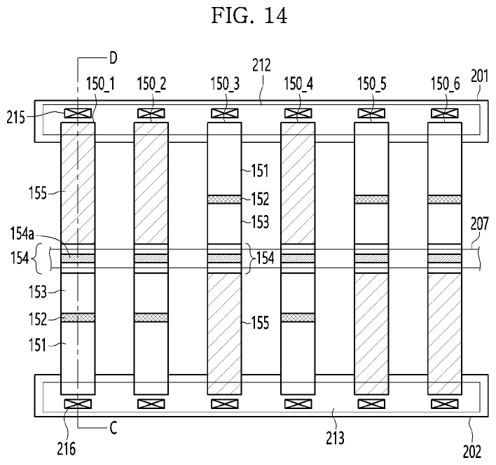

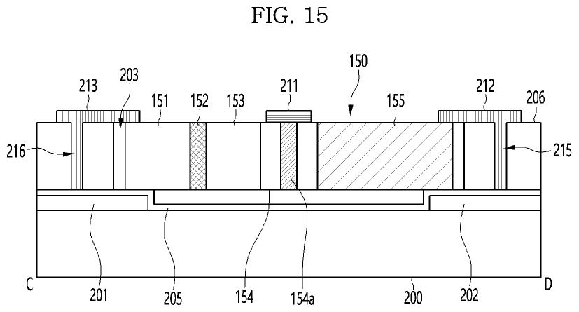

FIG. 14 is a plan view illustrating a third example of a display device having a light emitting device according to the first embodiment. FIG. 15 is a cross-sectional view taken along line C-D of FIG. 14.

In FIGS. 14 and 15, the first wiring line 201 and the second wiring line 202 can be used as an electrode line 211 for emitting light from the light emitting devices 150_1 to 150_6 that is, the second electrode line 208 shown in FIGS. 11 and 12. A first signal can be supplied to the electrode line 211, and a second signal can be simultaneously supplied to the first wiring line 201 and the second wiring line 202. Accordingly, the first wiring line 201 and the second wiring line 202 generate a dielectrophoretic force for assembling and fixing the light emitting devices 150_1 to 150_6 and can also serve to supply the a first signal for emitting light to the light emitting devices 150_1 to 150_6.

Referring to FIGS. 10, 14, and 15, a plurality of light emitting devices 150_1 to 150_6 manufactured according to the first embodiment can be assembled to a substrate 200. The plurality of light emitting devices 150_1 to 150_6 can be disposed along one direction, for example, a horizontal direction with reference to FIG. 11.

The display device of the embodiment can comprise a substrate 200, a plurality of first wiring lines 201, a plurality of second wiring lines 202, a first insulating member 205, a second insulating member 206, and a plurality of light emitting devices 150_1 to 150_6 and an electrode line 211.

The first wiring line 201, the second wiring line 202, the first insulating member 205, the second insulating member 206, and the light emitting devices 150_1 to 150_6 have been described with reference to FIGS. 11 and 12. Therefore, detailed descriptions are omitted.

The electrode line 211 can be disposed to cross central regions of the plurality of light emitting devices 150_1 to 150_6. For example, the electrode line 211 can contact the electrode layer 154 of each of the plurality of light emitting devices 150_1 to 150_6. Although not shown, the electrode line 211 can contact the second conductivity type semiconductor layer 153 of each of the plurality of light emitting devices 150_1 to 150_6.

The display device of the embodiment can comprise contact electrodes 212 and 213. For example, the contact electrodes 212 and 213 can comprise a first contact electrode 212 disposed along the first wiring line 201 and a second contact electrode 213 disposed along the second wiring line 202.

For example, the first contact electrode 212 can be disposed on a portion of the second insulating member 206 and a first side region of each of the plurality of light emitting devices 150_1 to 150_6. For example, the first contact electrode 212 can electrically connect the first wiring line 201 and the first side region of each of the plurality of light emitting devices 150_1 to 150_6.

The first side region of each of the plurality of light emitting devices 150_1 to 150_6 can be the first conductive semiconductor layer 151 or the insulating layer 155. For example, the second insulating member 206 can comprise a plurality of first contact holes 215. The number of first contact holes 215 can be the same as the number of the light emitting devices 150_1 to 150_6. The first contact hole 215 can be formed in the second insulating member 206 by etching the second insulating member 206 so that an upper surface of the first wiring line 201 can be exposed. A first contact electrode 212 can be disposed in the first contact hole 215. Accordingly, the first wiring line 201 and the first side region of each of the plurality of light emitting devices 150_1 to 150_6 can be electrically connected through the first contact electrode 212 disposed in each of the plurality of first contact holes 215.

For example, the second contact electrode 213 can be disposed on a portion of the second insulating member 206 and a second side region of each of the plurality of light emitting devices 150_1 to 150_6. For example, the second contact electrode 213 can electrically connect the second wiring line 202 and the second side region of each of the plurality of light emitting devices 1501 to 150_6.

The first side region of each of the plurality of light emitting devices 150_1 to 150_6 can be the first conductive semiconductor layer 151 or the insulating layer 155. For example, the second insulating member 206 can comprise a plurality of second contact holes 216. The number of second contact holes 216 can be the same as the number of the light emitting devices 150_1 to 150_6. The second contact hole 216 can be formed in the second insulating member 206 by etching the second insulating member 206 so that an upper surface of the second wiring line 202 can be exposed. A second contact electrode 213 can be disposed in the second contact hole 216. Accordingly, the second wiring line 202 and the second side region of each of the plurality of light emitting devices 150_1 to 150_6 can be electrically connected through the second contact electrode 213 disposed in each of the plurality of second contact holes 216.

Although not shown, after the light emitting devices 150_1 to 150_6 are assembled in the assembly hole 203 of the substrate 200 by the dielectrophoretic force between the first wiring line 201 and the second wiring line 202, the first wiring line 201 and the second wiring line 202 can be electrically connected. For example, the first wiring line 201 and the second wiring line 202 can be connected by turning on a switch. For example, the first wiring line 201 and the second wiring line 202 can be connected by a separate connection electrode.

The second signal supplied to the first wiring line 201 is supplied through the first contact electrode 212 to the first conductivity type semiconductor layer 151 of the light emitting devices 150_1 to 150_6 positioned on the first wiring line 201. The second signal supplied to the second wiring line 202 can be supplied through the second contact electrode 213 to the second conductivity type semiconductor layer 153 of the light emitting devices 150_1 to 1506 positioned on the second wiring line 202.

In the display device configured as described above, even if the plurality of light emitting devices 150_1 to 150_6 are arranged to have different assembly directions between the first wiring line 201 and the second wiring line 202, all light emitting devices 150_1 to 150_6 assembled on the substrate 200 can be emitted without defects by supplying the first signal to the electrode line 211 and supplying the second signal to the first wiring line 201 and the second wiring line 202.

Therefore, in the embodiment, since no defective light emitting device exists for each pixel, it is possible to significantly reduce costs by preventing waste of defective light emitting devices. In addition, since about 50% of the light emitting devices for each pixel can emit more light than in the related art, the luminance is remarkably improved, enabling a high luminance display. In addition, since defective light emitting devices do not occur for each pixel, when a uniform number of the light emitting devices is assembled in each pixel, a uniform luminance can be secured and more precise luminance control is possible.

Meanwhile, although not shown, spaces in the assembly hole 203 excluding the light emitting devices 150_1 to 150_6 can be filled with a separate insulating member so that the contact electrodes 212 and 214 can be more easily formed. For example, epoxy can be used as an insulating member, but is not limited thereto. Since an upper surface of the insulating member has the same position as an upper surface of the second insulating member 206 and/or an upper surface of the light emitting devices 150_1 to 150_6 the contact electrodes 212 and 214 can be easily formed.

### Second Embodiment

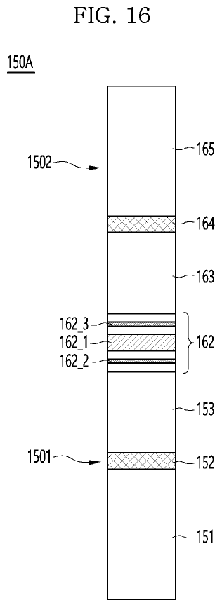

FIG. 16 is a cross-sectional view illustrating a light emitting device according to a second embodiment.

The second embodiment is similar to the first embodiment except that it has two light emitting devices 1501 and 1502 or two light emitting regions. In the second embodiment, the same reference numerals are assigned to components having the same functions, shapes and/or structures as those in the first embodiment, and detailed descriptions are omitted. For example, the two light emitting regions can be a first active layer 152 and a second active layer 164.

Referring to FIG. 16, the light emitting device 150A according to the second embodiment can comprise a first conductivity type semiconductor layer 151, a first active layer 152, a second conductivity type semiconductor layer 153, at least one or more electrode layers 162, a third conductivity type semiconductor layer, a second active layer 164, and a fourth conductivity type semiconductor layer 165. The first active layer 152 and the second active layer 164 can be referred to as a light emitting layer or a light emitting region.

For example, the first light emitting device 1501 can be constituted by the first conductivity type semiconductor layer 151, the first active layer 152, and the second conductivity type semiconductor layer 153, and the second light emitting device 1502 can be constituted by the third conductivity type semiconductor layer, the second active layer 164 and the fourth conductivity type semiconductor layer 165. Accordingly, the light emitting device according to the second embodiment can have two light emitting devices 1501 and 1502. In addition, since light is emitted from each of the first active layer 152 of the first light emitting device and the second active layer 164 of the second light emitting device, the light emitting device according to the second embodiment can have two light emitting regions.

Although a rod light emitting device is shown as the light emitting device 150A according to the second embodiment in the drawing, various light emitting devices are possible as an embodiment of the present invention. For example, a micro light emitting device, a disk light emitting device, a cylindrical light emitting device, or the like can be used as the light emitting device according to the first embodiment.

The cross section of the light emitting device 150A according to the second embodiment can have various shapes, such as circular, triangular, quadrangular, polygonal, or the like.

The first active layer 152 can be formed on the first conductivity type semiconductor layer 151, the second conductivity type semiconductor layer 153 can be formed on the first active layer 152, and at least one or more electrode layers 162 can be formed on the second conductivity type semiconductor layer 153. In addition, the third conductivity type semiconductor layer can be formed on the electrode layer 162, the second active layer 164 can be formed on the third conductivity type semiconductor layer, and the fourth conductivity type semiconductor layer 165 can be formed on the second active layer 164.

For example, the first conductivity type semiconductor layer 151 can comprise the same dopant as a dopant of the fourth conductivity type semiconductor layer 165. For example, the second conductivity type semiconductor layer 153 can comprise the same dopant as a dopant of the third conductivity type semiconductor layer. For example, the first conductivity type semiconductor layer 151 and the fourth conductivity type semiconductor layer 165 include an n-type dopant, and the second conductivity type semiconductor layer 153 and the third conductivity type semiconductor layer include a p-type dopant. Can comprise, but are not limited thereto.

For example, the electrode layer 162 can be positioned in the central region of the light emitting device 150A according to the second embodiment.

The electrode layer 162 can comprise at least one magnetic layer 162_2 or 162_3. The magnetic layer can allow the light emitting device 150A according to the second embodiment to be guided to a plurality of magnetic bodies when the assembly device (1100 in FIG. 9) comprising the plurality of magnetic bodies used for self-assembly moves.

The light emitting device 150A according to the second embodiment can be formed by combining two light emitting devices 1501 and 1502.

[Manufacturing process]

A manufacturing process of the light emitting device 150A according to the second embodiment will be described.

A plurality of light emitting devices can be manufactured by the manufacturing process of the light emitting device (150 in FIG. 10) according to the first embodiment described above. However, since the process of forming the insulating layer 155 is omitted in the manufacturing process of the light emitting device 150 according to the first embodiment, there is no insulating layer 155 in the light emitting device 150 manufactured above. At least one or more electrode layers 162 of the plurality of light emitting devices 150 manufactured above can comprise a bonding electrode layer 162_1. The bonding electrode layer 162_1 can be the uppermost layer of at least one or more electrode layers 162.

The plurality of light emitting devices 150 can comprise a first light emitting device 1501 composed of a first conductivity type semiconductor layer 151, a first active layer 152, a second conductivity type semiconductor layer 153 and at least one or more electrode layers 162. The plurality of light emitting devices 150 can comprise a second light emitting device 1502 composed of a fourth conductivity type semiconductor layer 165, a second active layer 164, a third conductivity type semiconductor layer 163 and at least one or more electrode layers 162.

In this case, in the first light emitting device, the first active layer 152 can be formed on the first conductivity type semiconductor layer 151, and the second conductivity type semiconductor layer 153 can be formed on the first active layer 152, the at least one or more electrode layers 162 can be formed on the second conductive semiconductor layer 153. In addition, in the second light emitting device, the second active layer 164 can be formed on the fourth conductivity type semiconductor layer 165, the third conductivity type semiconductor layer 163 can be formed on the second active layer 164, and the at least one or more electrode layers 162 can be formed on the third conductivity type semiconductor layer 163.

Thereafter, after the at least one or more electrode layers 162 of the first light emitting device and the at least one or more electrode layers 162 of the second light emitting device can be disposed to face each other, the first light emitting device and the second light emitting device can be pressed against each other. Accordingly, the bonding electrode layer 162_1 included in the at least one or more electrode layers 162 of the first light emitting device and the bonding electrode layer 162_1 included in the at least one or more electrode layers 162 of the second light emitting device can be combined to form a single bonding electrode layer 162_1. In addition, a light emitting device 150A according to the second embodiment in which the first light emitting device and the second light emitting device are combined can be manufactured. Therefore, the light emitting device 150A according to the second embodiment has at least one or more electrode layers 162 positioned in the central region thereof, and both sides of the electrode layer 162 can have a symmetrical structure. That is, the second conductivity type semiconductor layer 153 and the third conductivity type semiconductor layer 163 can be symmetrical with reference to the electrode layer 162, the first active layer 152 and the second active layer 164 can be symmetrical, and the first conductivity type semiconductor layer 151 and the fourth conductivity type semiconductor layer 165 can be symmetrical.

In the second embodiment, one light emitting device 150A can emit light in two different light emitting regions. Thus, the amount of light can be further increased and the luminance can be improved.

In the second embodiment, the number of the light emitting devices 150A assembled in each pixel can be reduced to obtain the same luminance in each pixel. Thus, assembly defects can be further reduced as the number of the light emitting devices 150A is reduced.

Meanwhile, although the bonding electrode layer 162_1 is adopted for the light emitting device 150A in the above, an insulating layer 155 can be used instead of the bonding electrode layer 162_1. Even if the insulating layer 155 is used, the manufacturing process of the light emitting device 150A according to the second embodiment can be performed in the same manner as the manufacturing process of the light emitting device 150A according to the second embodiment using the bonding electrode layer 162_1.

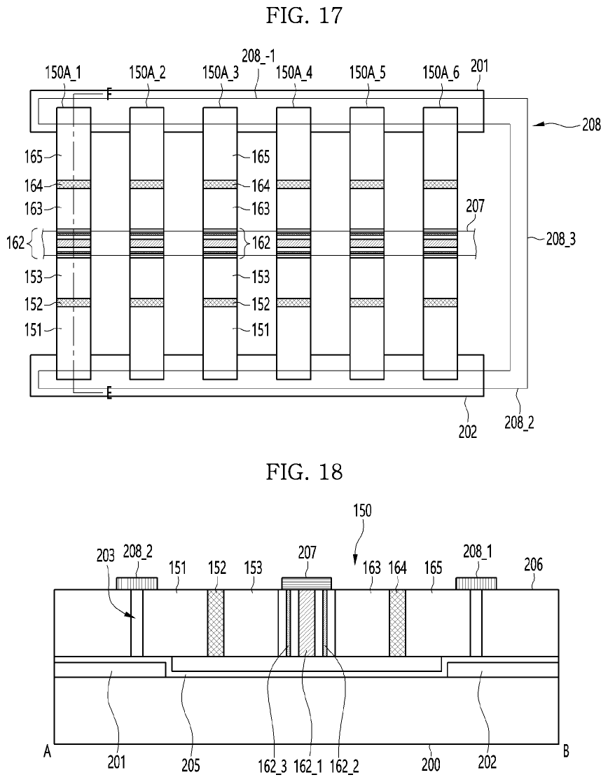

FIG. 17 is a plan view illustrating a first example of a display device having a light emitting device according to a second embodiment. FIG. 18 is a cross-sectional view taken along line E-F of FIG. 17.

The structure of the display device shown in FIGS. 17 and 18 is the same as the structure of the display device shown in FIGS. 11 and 12 except for the light emitting device 150A.

While the light emitting device 150 according to the first embodiment is adopted in the display device shown in FIGS. 11 and 12, the light emitting device 150A according to the second embodiment can be adopted in the display device shown in FIGS. 17 and 18.

Since the length of the major axis of the light emitting device 150A according to the second embodiment is greater than the length of the major axis of the light emitting device 150 according to the first embodiment, a separation distance between the first wiring line 201 and the second wiring line 202 in the display device shown in FIGS. 17 and 18 can be greater than the first wiring line 201 and the second wiring line 202 in the display device shown in FIGS. 11 and 12.

The display device can comprise a substrate 200, a plurality of first wiring lines 201, a plurality of second wiring lines 202, a first insulating member 205, a second insulating member 206, a plurality of light emitting devices 150A_1 to 150A_6, a first electrode line 207 and a second electrode line 208.

Since the first wiring line 201, the second wiring line 202, the first insulating member 205, and the second insulating member 206 have been described above, detailed descriptions are omitted.

For example, the first electrode line 207 can be disposed to cross the electrode layer 162 positioned in the central region of each of the plurality of light emitting devices 150A_1 to 150A_6. The first electrode line 207 can contact the electrode layer 162 of each of the plurality of light emitting devices 150A_1 to 150A_6. For example, the first electrode line 207 can contact the bonding electrode layer 162_1 of each of the plurality of light emitting devices 150A_1 to 150A_6. For example, the first electrode line 207 can contact the bonding electrode layer 162_1, the first magnetic layer 162_2, and/or the second magnetic layer 162_3 of each of the plurality of light emitting devices 150A_1 to 150A_6. For example, the first electrode line 207 can contact the electrode layer 162, the second conductivity type semiconductor layer 153, and/or the third conductivity type semiconductor layer 163 of each of the plurality of light emitting devices 150A_1 to 150A_6.

For example, the second electrode line 208 can be disposed to cross the first conductivity type semiconductor layer 151 or the fourth conductivity type semiconductor layer 165 positioned on both side regions of each of the plurality of light emitting devices 150A_1 to 150A_6.

The second electrode line 208 can comprise a second-first electrode line 208_1 disposed to cross the first conductive semiconductor layer 151 or the fourth conductive semiconductor layer 165 positioned in a first side region of each of the plurality of light emitting devices 150A_1 to 150A_6, and a second-second electrode line (208_2) disposed to cross the first conductivity type semiconductor layer 151 or the fourth conductivity type semiconductor layer 165 positioned in a second side region of each of the plurality of light emitting devices 150A_1 to 150A_6.

For example, the second-first electrode line 208_1 can contact the first conductivity type semiconductor layer 151 or the fourth conductivity type semiconductor layer 165 of the light emitting devices 150A_1 to 150A_6 positioned on the first wiring line 201. For example, the second-second electrode line 208_2 can contact the first conductivity type semiconductor layer 151 or the fourth conductivity type semiconductor layer 165 of the light emitting devices 150A_1 to 150A_6 positioned on the second wiring line 202.

For example, a first signal can be supplied to the first electrode line 207 and a second signal can be supplied to the second electrode line 208. In this case, the first signal is supplied to the second conductivity type semiconductor layer 153 and the third conductivity type semiconductor layer 163 through the first electrode line 207 and the electrode layers 162 of the light emitting devices 150A_1 to 150A_6.

The second signal can be supplied to the first conductivity type semiconductor layer 151 or the fourth conductivity type semiconductor layer 165 of the light emitting devices 150A_1 to 150A_6 through the second-first electrode line 208_1 of the second electrode line 208 and can be supplied to the first conductivity type semiconductor layer 151 or the fourth conductivity type semiconductor layer 165 of the light emitting devices 150A_1 to 150A_6 through the second-second electrode line 208_2 of the second electrode line 208.

Accordingly, since a current path can be formed and light is emitted from each of the first active layer 152 and the second active layer 164, the amount of light can be increased. In the current path, current can flow from the second conductivity type semiconductor layer 153 of each of the light emitting devices 150A_1 to 150A_6 to the first conductivity type semiconductor layer 151 and from the third conductivity type semiconductor layer 163 to the fourth conductivity type semiconductor layer 165.

Therefore, the display device in which the light emitting device 150A according to the second embodiment is adopted can obtain more improved luminance than the display device in which the light emitting device 150 according to the first embodiment is adopted.

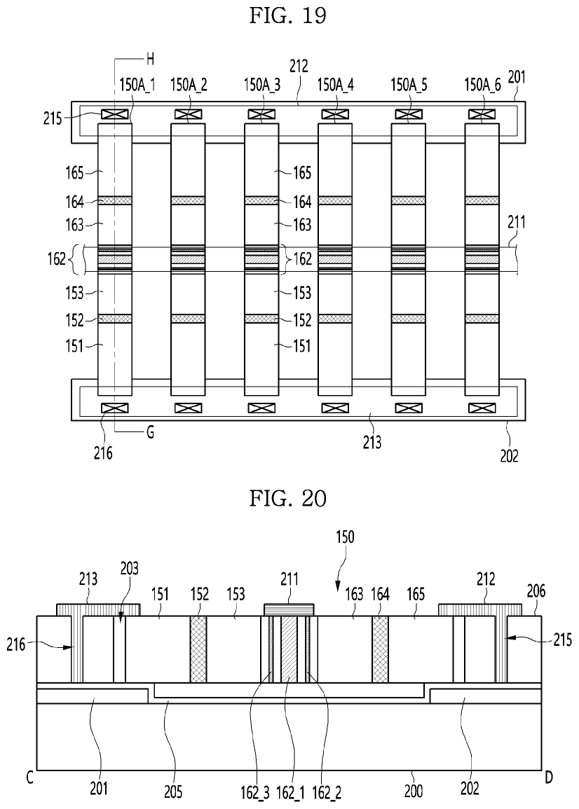

FIG. 19 is a plan view illustrating a second example of a display device having a light emitting device according to the second embodiment. FIG. 20 is a cross-sectional view taken along line G-H of FIG. 19.

The structure of the display device shown in FIGS. 19 and 20 is the same as the structure of the display device shown in FIGS. 14 and 15 except for the light emitting device 150A.

While the light emitting device 150 according to the first embodiment is adopted in the display device shown in FIGS. 14 and 15, the light emitting device 150A according to the second embodiment is adopted in the display device shown in FIGS. 19 and 20.

Since the length of the major axis of the light emitting device 150A according to the second embodiment is greater than the length of the major axis of the light emitting device 150 according to the first embodiment, the separation distance between the first wiring line 201 and the second wiring line 202 in the display device shown in FIGS. 19 and 20 can be greater than the separation distance between the first wiring line 201 the second wiring line 202 in the display device shown in FIGS. 14 and 15.

The display device of the embodiment can comprise a substrate 200, a plurality of first wiring lines 201, a plurality of second wiring lines 202, a first insulating member 205, a second insulating member 206, a plurality of light emitting devices 150A_1 to 150A_6, an electrode line 211, and contact electrodes 212 and 213.

Since the first wiring line 201, the second wiring line 202, the first insulating member 205, the second insulating member 206, and the light emitting devices 150A_1 to 150A_6 have been described above, detailed descriptions are omitted.

For example, the electrode line 211 can be disposed to cross the electrode layer 162 positioned in the central region of each of the plurality of light emitting devices 150A_1 to 150A_6. The electrode line 211 can contact the electrode layer 162 of each of the plurality of light emitting devices 150A_1 to 150A_6. For example, the electrode line 211 can contact the bonding electrode layer 162_1 of each of the plurality of light emitting devices 150A_1 to 150A_6. For example, the electrode line 211 can contact the bonding electrode layer 162_1, the first magnetic layer 1622, and/or the second magnetic layer 162_3 of each of the plurality of light emitting devices 150A_1 to 150A_6. For example, the electrode line 211 can contact the electrode layer 162, the second conductivity type semiconductor layer 153, and/or the third conductivity type semiconductor layer 163 of each of the plurality of light emitting devices 150A_1 to 150A_6.

For example, the contact electrodes 212 and 213 can comprise a first contact electrode 212 disposed along the first wiring line 201 and a second contact electrode 213 disposed along the second wiring line 202.

For example, the first contact electrode 212 can connect the first wiring line 201 through the first contact hole 215 to the first conductive semiconductor layer 151 or the fourth conductive semiconductor layer 165 of each of the plurality of light emitting devices 150A_1 to 150A_6. For example, the second contact electrode 213 can connect the second wiring line 202 through the second contact hole 216 to the first conductivity type semiconductor layer 151 or the fourth conductive semiconductor layer 165 of each of the plurality of light emitting devices 150A_1 to 150A_6.

Although not shown, after the light emitting devices 150A_1 to 150A_6 are assembled in the assembly hole 203 of the substrate 200 by the dielectrophoretic force between the first wiring line 201 and the second wiring line 202, the first wiring line 201 and the second wiring line 202 can be electrically connected. For example, the first wiring line 201 and the second wiring line 202 can be connected by turning on a switch. For example, the first wiring line 201 and the second wiring line 202 can be connected by a separate connection electrode.

The first signal can be supplied to the second conductivity type semiconductor layer 153 or the third conductivity type semiconductor layer 163 through the electrode line 211 and the electrode layer 162 of each of the light emitting devices 150A_1 to 150A_6.

The second signal supplied to the first wiring line 201 can be supplied to the first conductivity type semiconductor layer 151 or the fourth conductivity type semiconductor layer 165 of the light emitting devices 150A_1 to 150A_6 positioned on the first wiring line 201 through the first contact electrode 212. The second signal supplied to the second wiring line 202 can be supplied to the first conductivity type semiconductor layer 151 or the fourth conductivity type semiconductor layer 165 of the light emitting devices 150A_1 to 150A_6 positioned on the second wiring line 202 through the second contact electrode 213.

Accordingly, since a current path can be formed and light is emitted from each of the first active layer 152 and the second active layer 164, the amount of light can be increased. In the current path, current can flow from the second conductivity type semiconductor layer 153 of each of the light emitting devices 150A_1 to 150A_6 to the first conductivity type semiconductor layer 151 and from the third conductivity type semiconductor layer 163 to the fourth conductivity type semiconductor layer 165.

Therefore, the display device in which the light emitting device 150A according to the second embodiment is adopted can obtain more improved luminance than the display device in which the light emitting device 150 according to the first embodiment is adopted.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### INDUSTRIAL APPLICABILITY

The embodiment can be adopted in the display field for displaying images or information.

1. A light emitting device, comprising:
a first conductivity type semiconductor layer;
an active layer on the first conductivity type semiconductor layer;
a second conductivity type semiconductor layer on the active layer;
at least one or more electrode layers on the second conductivity type semiconductor layer; and
an insulating layer on the at least one or more electrode layers,
wherein at least one of the second conductivity type semiconductor layer and the electrode layer is configured to be positioned in the central region of the light emitting device.

2. The light emitting device of claim 1, wherein the boundary between the second conductivity type semiconductor layer and the electrode layer is configured to be positioned in the central region of the light emitting device.

3. The light emitting device of claim 1, wherein the electrode layer comprises a magnetic layer.

4. A display device, comprising:
a substrate;
a first wiring line on the substrate;
a second wiring line on the substrate;
an insulating member comprising a plurality of assembly holes on the first wiring line and the second wiring line;
a plurality of light emitting devices in each of the plurality of assembly holes;
a first electrode line configured to cross the central region of each of the plurality of light emitting devices; and
a second electrode line configured to cross both side regions of each of the plurality of light emitting devices,
wherein the light emitting device comprises:
a first conductivity type semiconductor layer;
an active layer on the first conductivity type semiconductor layer;
a second conductivity type semiconductor layer on the active layer;
at least one or more electrode layers on the second conductivity type semiconductor layer; and
an insulating layer on the at least one or more electrode layers,
wherein at least one of the second conductivity type semiconductor layer and the electrode layer is configured to be positioned in the central region of the light emitting device.

5. The display device of claim 4, wherein the first electrode line is configured to contact at least one of the second conductivity type semiconductor layer and the electrode layer.

6. The display device of claim 5, wherein the second electrode line comprises:
a second-first electrode line configured to contact a first side region of each of the plurality of light emitting devices;
a second-second electrode line configured to contact a second side region of each of the plurality of light emitting devices; and
a connection electrode configured to connect the second-first electrode line and the second-second electrode line.

7. The display device of claim 6, wherein the second-first electrode line is configured to contact one of the first conductivity type semiconductor layer and the insulating layer.

8. The display device of claim 6, wherein the second-second electrode line is configured to contact one of the first conductivity type semiconductor layer and the insulating layer.

9. A display device, comprising:
a substrate;
a first wiring line on the substrate;
a second wiring line on the substrate;
an insulating member comprising a plurality of assembly holes on the first wiring line and the second wiring line;
a plurality of light emitting devices in each of the plurality of assembly holes;
an electrode line configured to cross the central region of each of the plurality of light emitting devices; and
contact electrodes disposed on the insulating member and configured to connect both side regions of each of the plurality of light emitting devices to the first wiring line and the second wiring line,
wherein the light emitting device comprises:
a first conductivity type semiconductor layer;
an active layer on the first conductivity type semiconductor layer;
a second conductivity type semiconductor layer on the active layer;
at least one or more electrode layers on the second conductivity type semiconductor layer; and
an insulating layer on the at least one or more electrode layers,
wherein at least one of the second conductivity type semiconductor layer and the electrode layer is configured to be positioned in the central region of the light emitting device.

10. The display device of claim 9, wherein the first electrode line is configured to contact at least one of the second conductivity type semiconductor layer and the electrode layer.

11. The display device of claim 9, wherein the contact electrode comprises:
a first contact electrode configured to be connected to a first side region of each of the plurality of light emitting devices to the first wiring line through a contact hole; and
a second contact electrode configured to be connected to a second side region of each of the plurality of light emitting devices to the second wiring line through the contact hole.

12. The display device of claim 11, wherein the first contact electrode is configured to contact one of the first conductivity type semiconductor layer and the insulating layer.

13. The display device of claim 11, wherein the second contact electrode is configured to contact one of the first conductivity type semiconductor layer and the insulating layer.

14. A light emitting device, comprising:
a first conductivity type semiconductor layer;
a first active layer on the first conductivity type semiconductor layer;
a second conductivity type semiconductor layer on the first active layer;
at least one or more electrode layers on the second conductivity type semiconductor layer;
a third conductivity type semiconductor layer on the at least one or more electrode layers;
a second active layer on the third conductivity type semiconductor layer; and
a fourth conductivity type semiconductor layer on the second active layer,
wherein the first conductivity type semiconductor layer and the fourth conductivity type semiconductor layer comprise the same dopant,
wherein the second conductivity type semiconductor layer and the third conductivity type semiconductor layer comprise the same dopant, and
wherein the at least one or more electrode layers are configured to be positioned in the central region of the light emitting device.

15. The light emitting device of claim 14, wherein the first conductivity type semiconductor layer and the fourth conductivity type semiconductor layer comprise an n-type dopant, and
wherein the second conductivity type semiconductor layer and the third conductivity type semiconductor layer comprise a p-type dopant.

16. The light emitting device of claim 14, wherein the electrode layer comprises a magnetic layer.

17. A display device, comprising:
a substrate;
a first wiring line on the substrate;
a second wiring line on the substrate;
an insulating member comprising a plurality of assembly holes on the first wiring line and the second wiring line;
a plurality of light emitting devices in each of the plurality of assembly holes;
a first electrode line configured to cross the central region of each of the plurality of light emitting devices; and
a second electrode line configured to cross both side regions of each of the plurality of light emitting devices,
wherein the light emitting device comprises:
a first conductivity type semiconductor layer;
a first active layer on the first conductivity type semiconductor layer;
a second conductivity type semiconductor layer on the first active layer;
at least one or more electrode layers on the second conductivity type semiconductor layer;
a third conductivity type semiconductor layer on the at least one or more electrode layers;
a second active layer on the third conductivity type semiconductor layer; and
a fourth conductivity type semiconductor layer on the second active layer,
wherein the first conductivity type semiconductor layer and the fourth conductivity type semiconductor layer comprise the same dopant,
wherein the second conductivity type semiconductor layer and the third conductivity type semiconductor layer comprise the same dopant, and
wherein the at least one or more electrode layers are configured to be positioned in the central region of the light emitting device.

18. A display device, comprising:
a substrate;
a first wiring line on the substrate;
a second wiring line on the substrate;
an insulating member comprising a plurality of assembly holes on the first wiring line and the second wiring line;
a plurality of light emitting devices in each of the plurality of assembly holes; and
an electrode line configured to cross the central region of each of the plurality of light emitting devices; and
contact electrodes disposed on the insulating member and configured to connect both side regions of each of the plurality of light emitting devices to the first wiring line and the second wiring line,
wherein the light emitting device comprises:
a first conductivity type semiconductor layer;
a first active layer on the first conductivity type semiconductor layer;
a second conductivity type semiconductor layer on the first active layer;
at least one or more electrode layers on the second conductivity type semiconductor layer;
a third conductivity type semiconductor layer on the at least one or more electrode layers;
a second active layer on the third conductivity type semiconductor layer; and
a fourth conductivity type semiconductor layer on the second active layer,
wherein the first conductivity type semiconductor layer and the fourth conductivity type semiconductor layer comprise the same dopant,
wherein the second conductivity type semiconductor layer and the third conductivity type semiconductor layer comprise the same dopant, and
wherein the at least one or more electrode layers are configured to be positioned in the central region of the light emitting device.
